(19) United States
(12) Patent Application Publication
(10) Pub. No.: US 2026/0101508 A1
(43) Pub. Date: Apr. 9, 2026

(54) MEMORY DEVICE INCLUDING A PERFORATED DIELECTRIC BRIDGE LAYER AND METHOD FOR FORMING THE SAME

(71) Applicant: Sandisk Technologies, Inc., Milpitas, CA (US)

(72) Inventors: Koichi MATSUNO, Fremont, CA (US); Adarsh RAJASHEKHAR, Santa Clara, CA (US); Shuji MINAGAWA, Yokkaichi (JP)

(21) Appl. No.: 18/909,661

(22) Filed: Oct. 8, 2024

(51) Int. Cl. H10B 43/27; G11C 16/04; H10B 43/10; H10B 43/35

(52) U.S. Cl. CPC H10B 43/27; G11C 16/0483; H10B 43/10; H10B 43/35

(57) ABSTRACT

A memory device includes alternating stacks of insulating layers and electrically conductive layers, and arrays of memory stack structure. The alternating stacks are laterally spaced apart from each other by lateral isolation trenches that laterally extend along a first horizontal direction. Each array of memory stack structures vertically extends through a respective one of the alternating stacks, and includes a respective vertical semiconductor channel and a vertical stack of memory elements located at levels of the electrically conductive layers. A perforated dielectric bridge layer laterally extends over each of the alternating stacks and each of the lateral isolation trenches and includes rows of elongated openings therethrough. Each row of elongated openings overlies a respective one of the lateral isolation trenches and extends along the first horizontal direction.

### FIELD

The present disclosure relates generally to the field of semiconductor devices, and particularly to a memory device including a perforated dielectric bridge layer and methods for manufacturing the same.

### BACKGROUND

Three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a memory device includes: alternating stacks of insulating layers and electrically conductive layers, wherein the alternating stacks are laterally spaced apart from each other by lateral isolation trenches that laterally extend along a first horizontal direction; arrays of memory stack structures, wherein each array of memory stack structures vertically extends through a respective one of the alternating stacks, and each of the memory stack structures comprises a respective vertical semiconductor channel and a vertical stack of memory elements; and a perforated dielectric bridge layer laterally extending over each of the alternating stacks and each of the lateral isolation trenches and comprising rows of elongated openings therethrough, wherein each row of elongated openings overlies a respective one of the lateral isolation trenches and extends along the first horizontal direction.

According to another aspect of the present disclosure, a method of forming a device structure is provided, which comprises: forming a plurality of alternating stacks of insulating layers and sacrificial material layers that are laterally spaced apart from each other by lateral isolation trenches that laterally extend along a first horizontal direction; forming sacrificial lateral isolation wall structures in the lateral isolation trenches; forming a perforated dielectric bridge layer over the plurality of alternating stacks and sacrificial lateral isolation wall structures, wherein the perforated dielectric bridge layer comprises rows of elongated openings therethrough, and wherein each row of elongated openings overlies a respective one of the sacrificial lateral isolation wall structures and is arranged along the first horizontal direction; removing the sacrificial lateral isolation wall structures through the rows of elongated openings without removing the plurality of alternating stacks or the perforated dielectric bridge layer; and replacing the sacrificial material layers with at least electrically conductive layers.

### BRIEF DESCRIPTION OF THE DRAWINGS

FIG. 1 is a schematic vertical cross-sectional view of an exemplary structure after formation of a vertically alternating sequence of continuous insulating layers and continuous sacrificial material layers over a carrier substrate according to a first embodiment of the present disclosure.

FIG. 2 is a schematic vertical cross-sectional view of the exemplary structure after formation of stepped surfaces and a retro-stepped dielectric material portion according to an embodiment of the present disclosure.

FIG. 3A is a schematic vertical cross-sectional view of the exemplary structure after formation of memory openings and support openings according to an embodiment of the present disclosure. FIG. 3B is a top-down view of the exemplary structure of FIG. 3A. The hinged vertical cross-sectional plane A-A′ is the cut plane of the vertical cross-sectional view of FIG. 3A.

FIG. 4 is a schematic vertical cross-sectional view of the exemplary structure after formation of sacrificial opening fill structures according to an embodiment of the present disclosure.

FIG. 5 is a vertical cross-sectional view of the exemplary structure after formation of support pillar structures according to an embodiment of the present disclosure.

FIG. 6 is a schematic vertical cross-sectional view of the exemplary structure after removal of sacrificial memory opening fill structures according to an embodiment of the present disclosure.

FIG. 7A-7F are sequential vertical cross-sectional views of a memory opening during formation of a memory opening fill structure according to an embodiment of the present disclosure.

FIG. 8A is a schematic vertical cross-sectional view of the exemplary structure after formation of memory opening fill structures according to an embodiment of the present disclosure. FIG. 8B is a top-down view of the exemplary structure of FIG. 8A. The vertical plane A-A is the cut plane of the vertical cross-sectional view of FIG. 8A.

FIG. 9A is a vertical cross-sectional view of the exemplary structure after formation of a contact-level dielectric layer and lateral isolation trenches according to an embodiment of the present disclosure. FIG. 9B is a top-down view of the exemplary structure of FIG. 9A. The vertical plane A-A is the cut plane of the vertical cross-sectional view of FIG. 9A.

FIG. 10A is a vertical cross-sectional view of the exemplary structure after formation of sacrificial lateral isolation wall structures in the lateral isolation trenches according to an embodiment of the present disclosure. FIG. 10B is a top-down view of the exemplary structure of FIG. 10A. The vertical plane A-A is the cut plane of the vertical cross-sectional view of FIG. 10A.

FIG. 11A is a vertical cross-sectional view of the exemplary structure after formation of a perforated dielectric bridge layer according to an embodiment of the present disclosure. FIG. 11B is a top-down view of the exemplary structure of FIG. 11A. The vertical plane A-A is the cut plane of the vertical cross-sectional view of FIG. 11A.

FIG. 12A is a vertical cross-sectional view of the exemplary structure after removal of sacrificial lateral isolation wall structures from the lateral isolation trenches according to an embodiment of the present disclosure. FIG. 12B is a top-down view of the exemplary structure of FIG. 12A. The vertical plane A-A is the cut plane of the vertical cross-sectional view of FIG. 12A.

FIG. 13 is a vertical cross-sectional view of the exemplary structure after formation of laterally-extending cavities according to an embodiment of the present disclosure.

FIG. 14 is a schematic vertical cross-sectional view of the exemplary structure after formation of electrically conductive layers according to an embodiment of the present disclosure.

FIG. 15 is a schematic vertical cross-sectional view of the exemplary structure after formation of a dielectric fill material layer according to an embodiment of the present disclosure.

FIG. 16A is a vertical cross-sectional view of the exemplary structure after formation of lateral isolation wall structures according to an embodiment of the present disclosure. FIG. 16B is a top-down view of the exemplary structure of FIG. 16A. The vertical plane A-A is the cut plane of the vertical cross-sectional view of FIG. 16A. FIG. 16C is a vertical cross-sectional view of the exemplary structure along the vertical plane C-C′ of FIG. 16B. FIG. 16D is a vertical cross-sectional view of an alternative exemplary structure after formation of an alternative lateral isolation wall structures according to an alternative embodiment of the present disclosure.

FIG. 17A is a vertical cross-sectional view of the exemplary structure after formation of drain-select-level isolation trenches according to an embodiment of the present disclosure. FIG. 17B is a top-down view of the exemplary structure of FIG. 17A. The vertical plane A-A is the cut plane of the vertical cross-sectional view of FIG. 17A.

FIG. 18A is a vertical cross-sectional view of the exemplary structure after formation of drain-select-level isolation structures according to an embodiment of the present disclosure. FIG. 18B is a top-down view of the exemplary structure of FIG. 18A. The vertical plane A-A is the cut plane of the vertical cross-sectional view of FIG. 18A.

FIG. 19A is a vertical cross-sectional view of the exemplary structure after formation of layer contact via cavities according to an embodiment of the present disclosure. FIG. 19B is a top-down view of the exemplary structure of FIG. 19A. The hinged vertical cross-sectional plane A-A′ in FIG. 19B is the cut plane of the vertical cross-sectional view of FIG. 19A.

FIG. 20 is a vertical cross-sectional view of the exemplary structure after formation of drain contact via cavities according to an embodiment of the present disclosure.

FIG. 21A is a vertical cross-sectional view of the exemplary structure after formation of layer contact via structures and drain contact via cavities according to an embodiment of the present disclosure. FIG. 21B is a top-down view of the exemplary structure of FIG. 21A. The hinged vertical cross-sectional plane A-A′ in FIG. 21B is the cut plane of the vertical cross-sectional view of FIG. 21A.

FIG. 22 is a vertical cross-sectional view of the exemplary structure after formation of a memory die according to an embodiment of the present disclosure.

FIG. 23 is a vertical cross-sectional view of a logic die according to an embodiment of the present disclosure.

FIG. 24 is a vertical cross-sectional view of the exemplary structure after attaching the logic die to the memory die according to an embodiment of the present disclosure.

FIG. 25 is a vertical cross-sectional view of the exemplary structure after removal of the carrier substrate according to an embodiment of the present disclosure.

FIG. 26 is a vertical cross-sectional view of the exemplary structure after formation of a source layer and backside contact structures according to an embodiment of the present disclosure.

### DETAILED DESCRIPTION

Embodiments of the present disclosure are directed to a memory device including a perforated dielectric bridge layer and methods for manufacturing the same. Embodiments of the disclosure can be employed to form various structures including a three-dimensional memory structure, non-limiting examples of which include three-dimensional NAND memory devices.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased in a single erase operation. Each block contains a number of pages, which may be the smallest unit that can be programmed, i.e., a smallest unit on which a read operation can be performed.

As used herein, a “semiconducting material” refers to a material having electrical conductivity in the range from 1×10⁻⁵ S/m to 1×10⁵ S/m. As used herein, a “semiconductor material” refers to a material having electrical conductivity in the range from 1×10⁻⁵ S/m to 1 S/m in the absence of electrical dopants therein, and is capable of producing a doped material having electrical conductivity in a range from 1 S/m to 1×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1×10⁵ S/m. As used herein, an “insulator material” or a “dielectric material” refers to a material having electrical conductivity less than 1×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1×10⁻⁵ S/m to 1×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

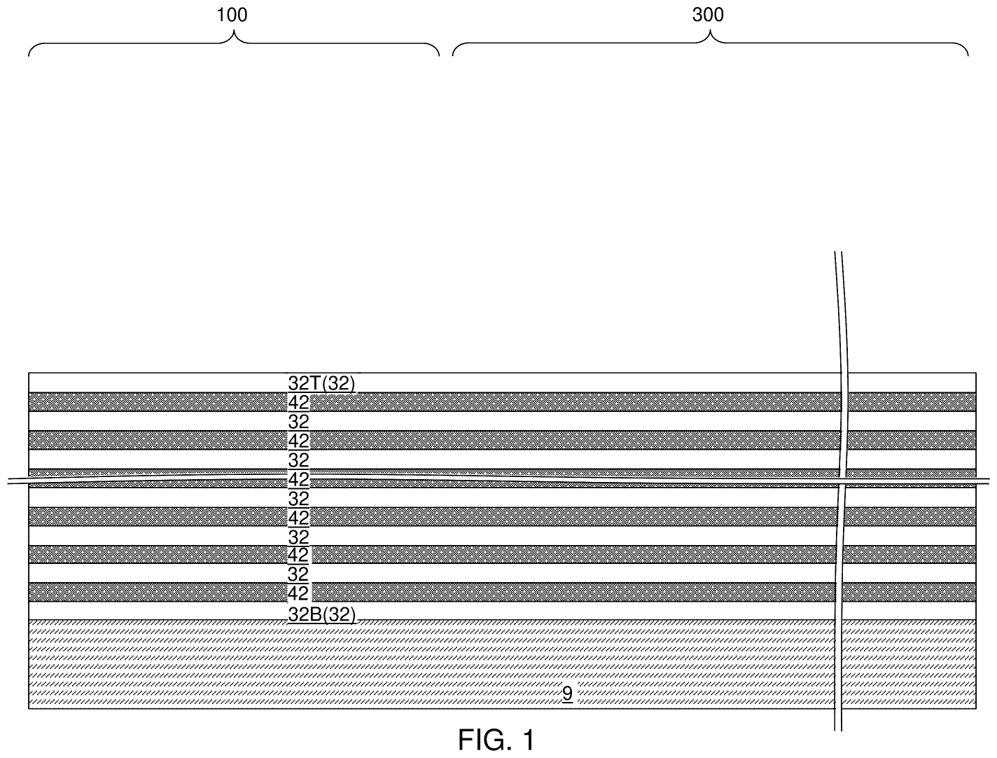

Referring to FIG. 1, an exemplary structure according to an embodiment of the present disclosure is illustrated. The exemplary structure comprises a carrier substrate 9, which may be a semiconductor substrate or a conductive substrate. For example, the carrier substrate 9 may comprise a commercially available silicon wafer. Alternatively, the carrier substrate 9 may comprise any material that may be removed selectively to the materials of continuous insulating layers 32C and dielectric material portions to be subsequently formed.

A vertically alternating sequence of first material layers and second material layers can be formed over the carrier substrate 9. The first material layers may be continuous insulating layers 32C, and the second material layers may be spacer material layers. In one embodiment, the spacer material layers may comprise continuous sacrificial material layers 42C. In this case, a vertically alternating sequence (32C, 42C) of continuous insulating layers 32C and continuous sacrificial material layers 42C can be formed over the carrier substrate 9. The continuous insulating layers 32C comprise an insulating material such as undoped silicate glass or a doped silicate glass, and the continuous sacrificial material layers 42C comprise a sacrificial material such as silicon nitride or a silicon-germanium alloy. In one embodiment, the continuous insulating layers 32C (i.e., the first material layers) may comprise silicon oxide layers, and the continuous sacrificial material layers 42C (i.e., the second material layers) may comprise silicon nitride layers. Each of the continuous insulating layers 32C and the continuous sacrificial material layers 42C may continuously extend over the entire area of the carrier substrate 9.

The vertically alternating sequence (32C, 42C) may comprise multiple repetitions of a unit layer stack including an continuous insulating layer 32C and a continuous sacrificial material layer 42C. The total number of repetitions of the unit layer stack within the vertically alternating sequence (32C, 42C) may be, for example, in a range from 8 to 1,024, such as from 32 to 256, although lesser and greater number of repetitions may also be employed. The topmost one of the continuous insulating layers 32C is hereafter referred to as a topmost continuous insulating layer 32CT. The bottommost one of the continuous insulating layers 32C (i.e., an continuous insulating layer 32C that is most proximal to the carrier substrate 9) is herein referred to as a bottommost continuous insulating layer 32CB.

Each of the continuous insulating layers 32C other than the topmost continuous insulating layer 32CT may have a thickness in a range from 20 nm to 100 nm, such as from 30 nm to 60 nm, although lesser and greater thicknesses may also be employed. Each of the continuous sacrificial material layers 42C may have a thickness in a range from 20 nm to 100 nm, such as from 30 nm to 60 nm, although lesser and greater thicknesses may also be employed. In one embodiment, the topmost continuous insulating layer 32CT may have a thickness of about one half of the thickness of other continuous insulating layers 32C.

The exemplary structure comprises a memory array region 100 in which a three-dimensional array of memory elements is to be subsequently formed, and a contact region 300 in which layer contact via structures contacting word lines are to be subsequently formed.

While an embodiment is described in which the spacer material layers are formed as continuous sacrificial material layers 42C, the spacer material layers may be formed as electrically conductive layers in an alternative embodiment. Generally, spacer material layers of the present disclosure may be formed as, or may be subsequently replaced at least partly with, electrically conductive layers.

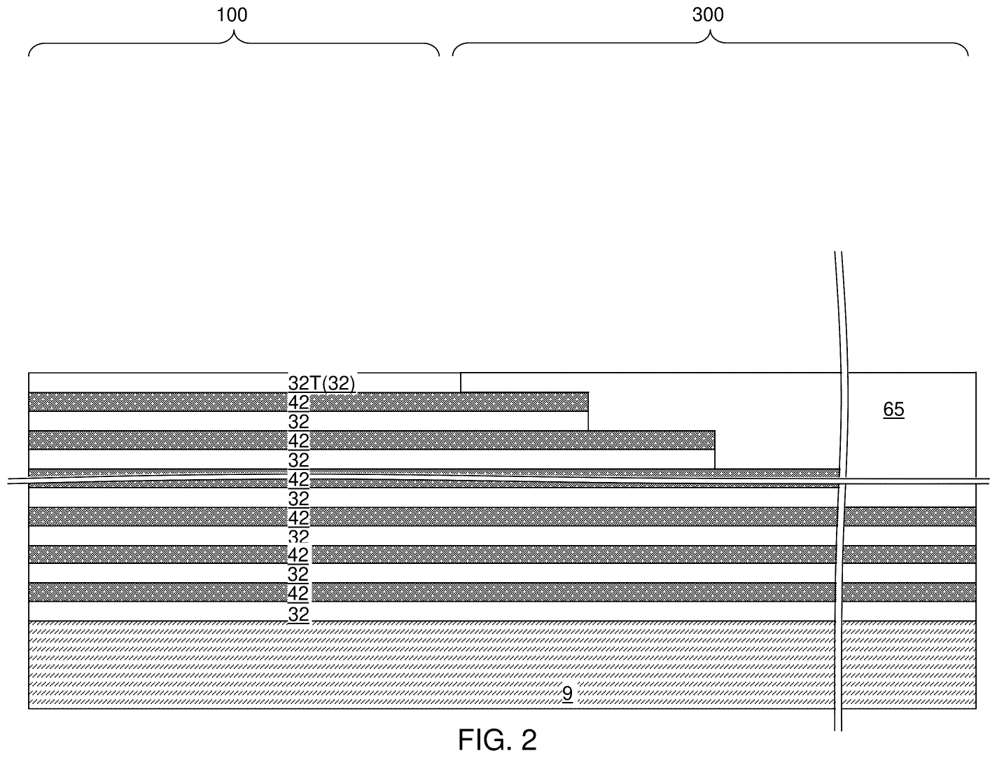

Referring to FIG. 2, optional stepped surfaces are formed in the contact region 300. As used herein, “stepped surfaces” refer to a set of surfaces that include at least two horizontal surfaces and at least two vertical surfaces such that each horizontal surface is adjoined to a first vertical surface that extends upward from a edge of the horizontal surface, and is adjoined to a second vertical surface that extends downward from a second edge of the horizontal surface. A stepped cavity is formed within the volume from which portions of the vertically alternating sequence (32C, 42C) are removed through formation of the stepped surfaces. A “stepped cavity” refers to a cavity having stepped surfaces.

The stepped cavity can have various stepped surfaces such that the horizontal cross-sectional shape of the stepped cavity changes in steps as a function of the vertical distance from the top surface of the carrier substrate 9. In one embodiment, the stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each continuous sacrificial material layer 42C other than a topmost continuous sacrificial material layer 42C within the vertically alternating sequence (32C, 42C) laterally extends farther than any overlying continuous sacrificial material layer 42C within the vertically alternating sequence (32C, 42C) in the terrace region. The stepped surfaces of the vertically alternating sequence (32C, 42C) continuously extend from a bottommost layer within the vertically alternating sequence (32C, 42C) (such as the bottommost continuous insulating layer 32CB) to a topmost layer within the vertically alternating sequence (32C, 42C) (such as the topmost continuous insulating layer 32CT).

A retro-stepped dielectric material portion 65 (i.e., an insulating fill material portion) can be formed in the stepped cavity by deposition of a dielectric material therein. For example, a dielectric material such as silicon oxide can be deposited in the stepped cavity. Excess portions of the deposited dielectric material can be removed from above the top surface of the topmost continuous insulating layer 32CT, for example, by chemical mechanical planarization (CMP). The remaining portion of the deposited dielectric material filling the stepped cavity constitutes the retro-stepped dielectric material portion 65. As used herein, a “stepped” element refers to an element that has stepped surfaces and a horizontal cross-sectional area that increases or decreases stepwise as a function of a vertical distance from a top surface of a substrate on which the element is present. If silicon oxide is employed for the retro-stepped dielectric material portion 65, the silicon oxide of the retro-stepped dielectric material portion 65 may optionally be doped with dopants such as B, P, and/or F.

In summary, a vertically alternating sequence of continuous insulating layers 32C and spacer material layers over a substrate such as a carrier substrate 9. The spacer material layers are formed as or are subsequently replaced with electrically conductive layers. Stepped surfaces are formed by patterning the vertically alternating sequence (32C, 42C). Lateral extents of the spacer material layer (such as the continuous sacrificial material layers 42C) vary with a vertical distance from a horizontal plane from the substrate. A retro-stepped dielectric material portion 65 can be formed over the stepped surfaces. The retro-stepped dielectric material portion 65 overlies the staircase region of the vertically alternating sequence and has a stepped bottom surface that contains horizontally-extending surface segments that are vertically offset from each other and adjoined to each other by vertically-extending surface segments.

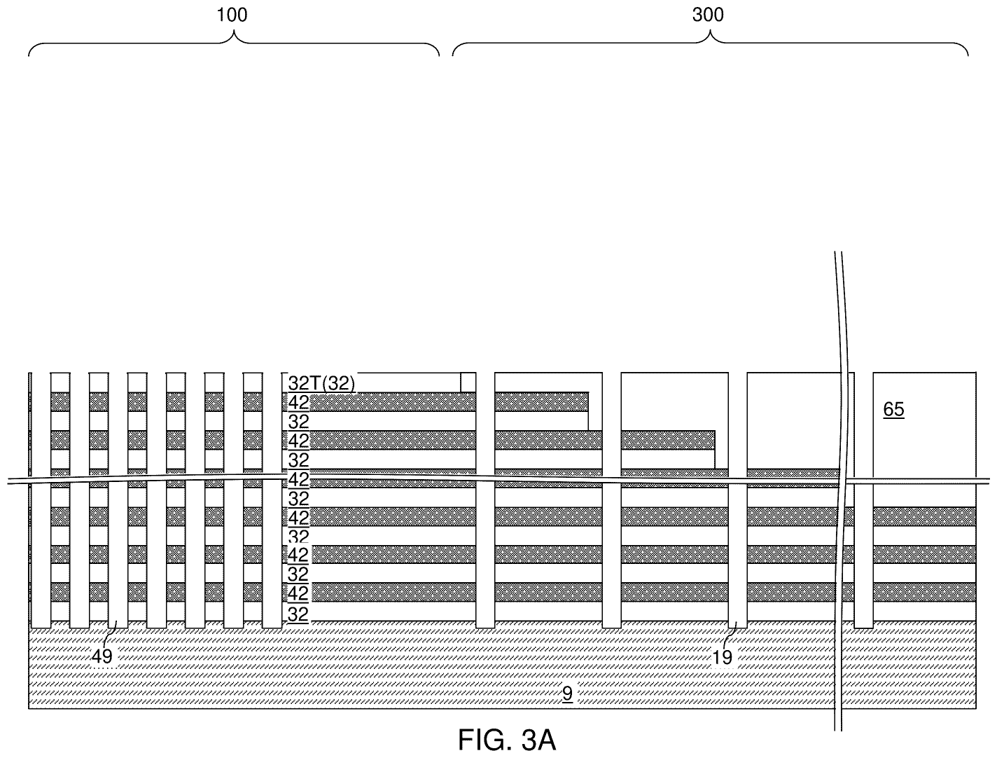

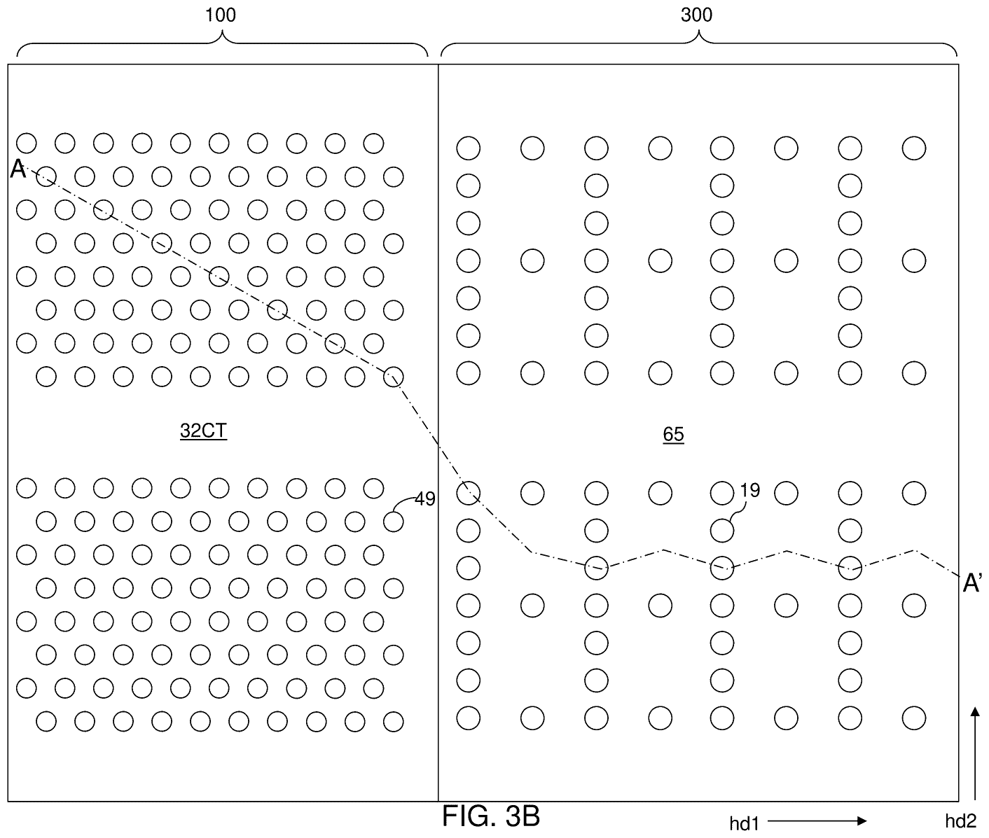

Referring to FIGS. 3A and 3B, an etch mask layer (such as a photoresist layer) can be formed over the vertically alternating sequence (32C, 42C), and can be lithographically patterned to form openings in the memory array region 100 and in the contact region 300. An anisotropic etch process can be performed to transfer the pattern of the openings in the etch mask layer through the retro-stepped dielectric material portion 65 and the vertically alternating sequence (32C, 42C). Memory openings 49 are formed through the vertically alternating sequence (32C, 42C) in the memory array region 100. Support openings 19 can optionally be formed through the retro-stepped dielectric material portion 65 and the vertically alternating sequence (32C, 42C) in the contact region 300.

Each of the memory openings 49 and the support openings 19 can vertically extend into the carrier substrate 9. In one embodiment, bottom surfaces of the memory openings 49 and the support openings 19 may be formed at or below the top surface of the carrier substrate 9. The memory openings 49 may have a diameter in a range from 60 nm to 400 nm, such as from 120 nm to 300 nm, although lesser and greater diameters may be employed. The support openings 19 may have a diameter in a range from 60 nm to 400 nm, such as from 120 nm to 300 nm, although lesser and greater diameters may be employed.

Each cluster of memory openings 49 (which corresponds to an area of a memory block) may comprise a plurality of rows of memory openings 49. Each row of memory openings 49 may comprise a plurality of memory openings 49 that are arranged along the first horizontal direction hd1 (which may be a word line direction) with a uniform pitch. The rows of memory openings 49 may be laterally spaced from each other along the second horizontal direction hd2 (which may be a bit line direction), which may be perpendicular to the first horizontal direction hd1. In one embodiment, each cluster of memory openings 49 may be formed as a two-dimensional periodic array of memory openings 49.

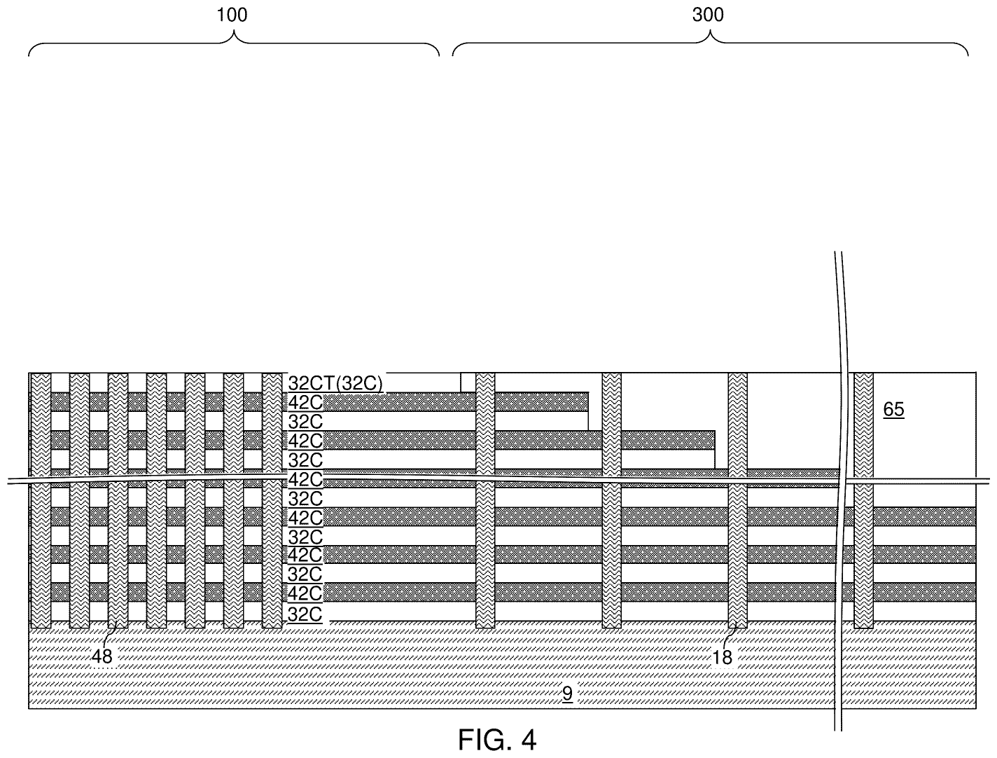

Referring to FIG. 4, an optional sacrificial liner layer (such as a thin silicon oxide layer) and a sacrificial fill material can be deposited in the memory openings 49 and in the support openings 19. The sacrificial fill material may comprise a carbon-based material (such as amorphous carbon or diamond-like carbon), a semiconductor material such as amorphous silicon or silicon-germanium), a polymer material, or a dielectric material (such as organosilicate glass or borosilicate glass). Excess portions of the sacrificial fill material may be removed from above the horizontal plane including the top surface of the topmost continuous insulating layer 32CT. Each remaining portion of the sacrificial fill material that fills a memory opening 49 constitutes a sacrificial memory opening fill structure 48. Each remaining portion of the sacrificial fill material that fills a support opening 19 constitutes a sacrificial support opening fill structure 18.

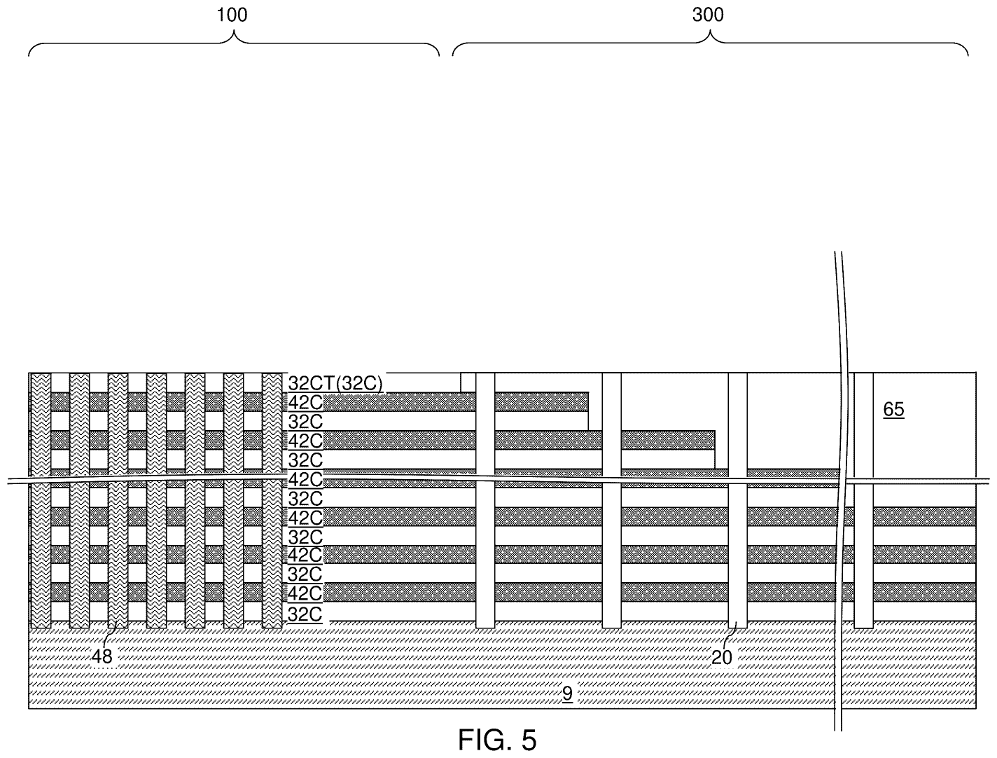

Referring to FIG. 5, a photoresist layer (not shown) can be applied over the exemplary structure, and can be lithographically patterned to cover the sacrificial memory opening fill structures 48 in the memory array region 100 without covering the sacrificial support opening fill structures 18 in the contact region 300. The sacrificial support opening fill structures 18 are subsequently removed selectively to the materials of the continuous insulating layers 32C, the continuous sacrificial material layers 42C, and the carrier substrate 9 by ashing or selective etching. Voids are formed in the volumes of the support openings 19 from which the sacrificial support opening fill structures 18 are removed.

A dielectric fill material, such as silicon oxide, can be deposited in the support openings 19 by a conformal deposition process. Excess portions of the dielectric fill material can be removed from above the top surface of the topmost continuous insulating layer 32CT, for example, by a recess etch process. Each portion of the dielectric fill material that fills a respective support opening 19 constitutes a support pillar structure 20, which can be employed to provide structural support to the continuous insulating layers 32C and the retro-stepped dielectric material portion 65 during replacement of the continuous sacrificial material layers 42C with electrically conductive layers. Alternatively, the support openings 19 can be formed at a later step at the same time as the memory openings, and the support pillar structures 20 can be formed in the support openings 19 at the same time as the memory opening fill structures are formed in the memory openings, as will be described below.

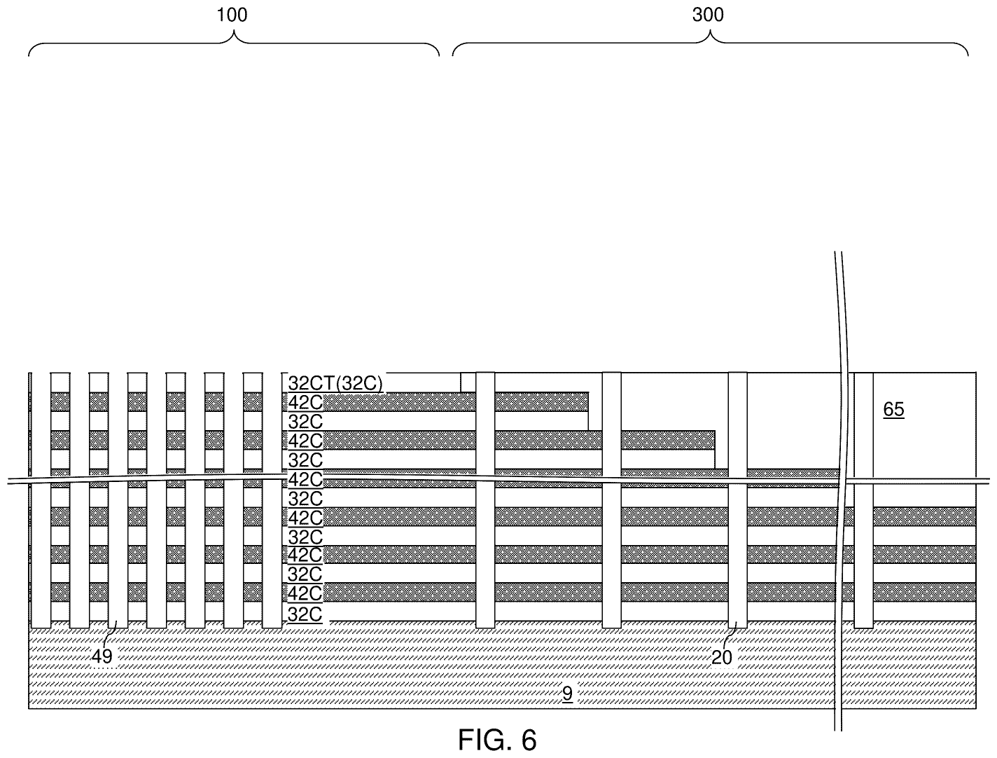

Referring to FIG. 6, sacrificial memory opening fill structures 48 are subsequently removed selectively to the materials of the continuous insulating layers 32C, the continuous sacrificial material layers 42C, and the carrier substrate 9. Voids are formed in the volumes of the memory openings 49 from which the sacrificial memory opening fill structures 48 are removed.

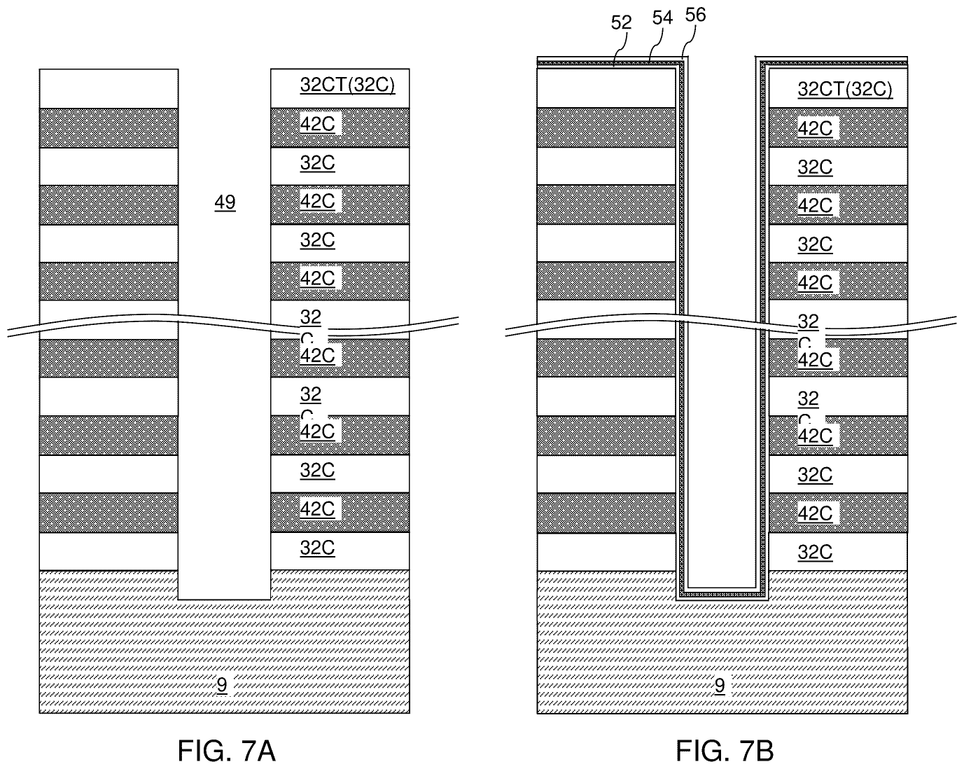

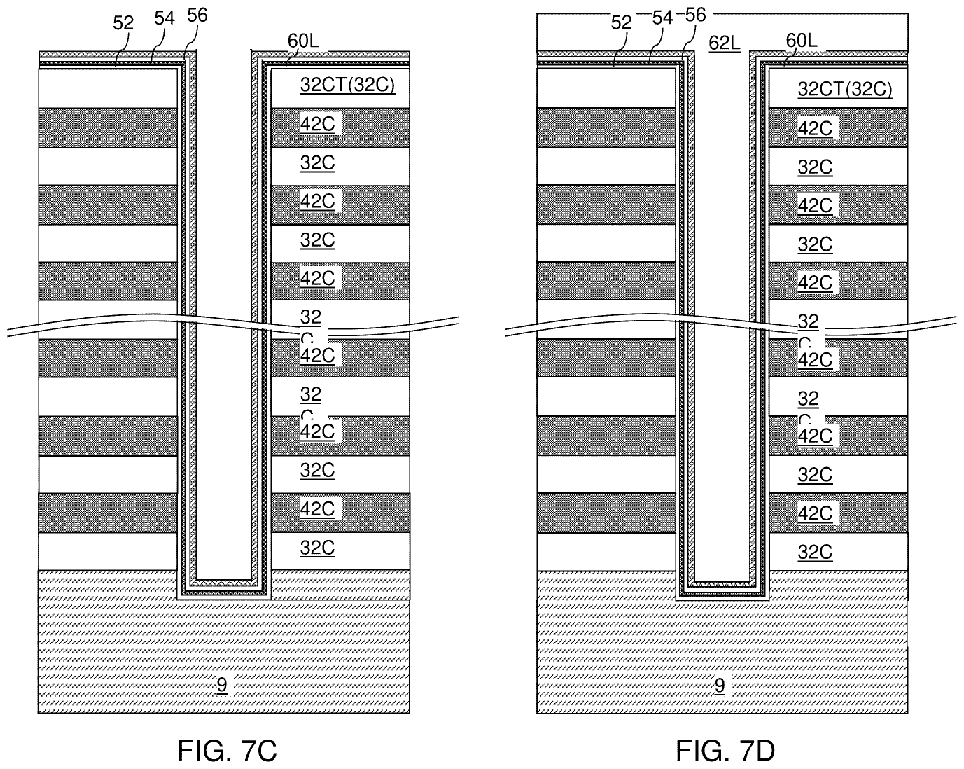

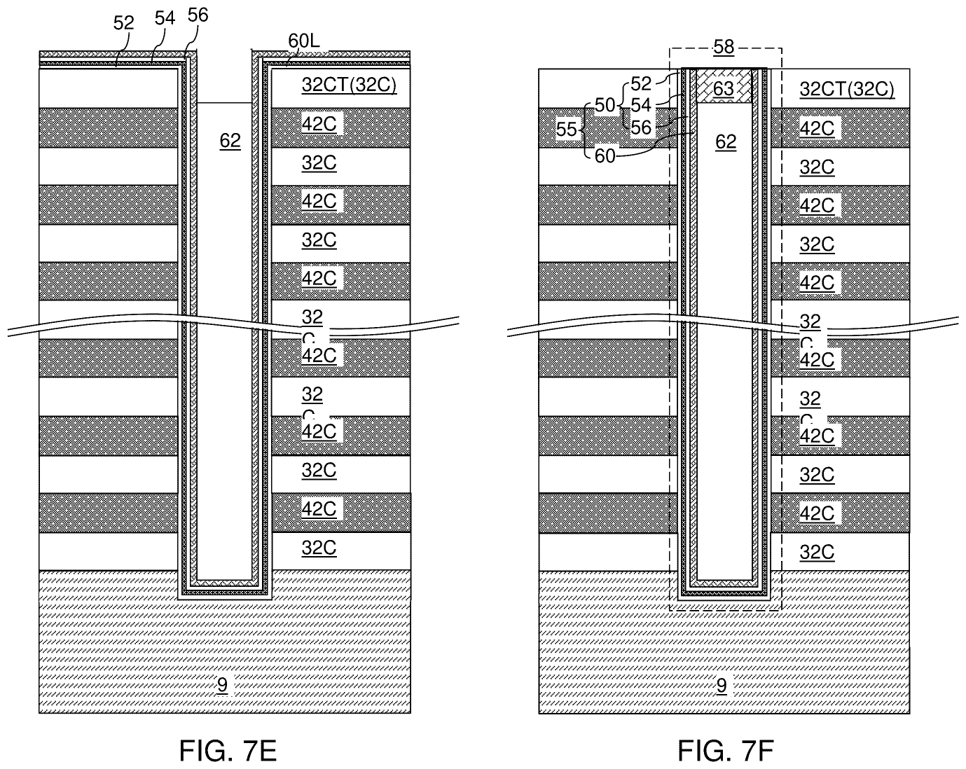

FIG. 7A-7F are sequential vertical cross-sectional views of a memory opening 49 during formation of a memory opening fill structure 58 according to an embodiment of the present disclosure.

Referring to FIG. 7A, a memory opening 49 is illustrated after the processing steps of FIG. 6.

Referring to FIG. 7B, a layer stack including a memory material layer 54 can be conformally deposited. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride), a ferroelectric material, a phase change memory material, or any other memory material that can store data bits by inducing a change in the electrical resistivity, ferroelectric polarization, or any other measurable physical property. In case the memory material layer 54 comprises a charge storage material, the optional dielectric liner 56 may comprise a tunneling dielectric layer.

Referring to FIG. 7C, a semiconductor channel material layer 60L can be deposited over the layer stack (52, 54, 56) by performing a conformal deposition process. If the semiconductor channel material layer 60L is doped, the semiconductor channel material layer 60L may have a doping of a first conductivity type, which may be p-type or n-type. The thickness of the semiconductor channel material layer 60L may be in a range from 5 nm to 50 nm, such as from 10 nm to 30 nm, although lesser and greater thicknesses may also be employed.

Referring to FIG. 7D, a dielectric core layer 62L comprising a dielectric fill material, such as silicon oxide, can be deposited in remaining volumes of the memory openings 49. The dielectric core layer 62L can be deposited employing a conformal deposition process, such as a chemical vapor deposition process.

Referring to FIG. 7E, the dielectric core layer 62L can be vertically recessed such that each remaining portion of the dielectric core layer has a top surface at, or about, the horizontal plane including the bottom surface of the topmost continuous insulating layer 32CT. Each remaining portion of the dielectric core layer constitutes a dielectric core 62.

Referring to FIG. 7F, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5×10¹⁸/cm³ to 2×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel material layer 60L can be removed from above the horizontal plane including the top surface of the topmost continuous insulating layer 32CT, for example, by chemical mechanical planarization (CMP) or a recess etch process. Each remaining portion of the doped semiconductor material having a doping of the second conductivity type constitutes a drain region 63. Each remaining portion of the semiconductor channel material layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination a memory stack structure 55, a dielectric core 62, and a drain region 63 within a memory opening 49 constitutes a memory opening fill structure 58. Each memory opening fill structure 58 comprises a respective vertical stack of memory elements, which may comprise portions of the memory material layer 54 located at levels of the continuous sacrificial material layers 42C, or generally speaking, at levels of spacer material layers that may be formed as, or may be subsequently replaced at least partly with, electrically conductive layers.

Generally, memory opening fill structures 58 can be formed in the memory openings 49. Each memory opening fill structure 58 comprises a memory stack structures 55. Each memory stack structure 55 vertically extends through the vertically alternating sequence (32C, 42C), and comprises a respective vertical stack of memory elements and a respective vertical channel 60 having an upper end that contacts a respective drain region 63. In one embodiment, each vertical stack of memory elements may comprise portions of a memory material layer 54 located at the levels of the continuous sacrificial material layers 42C.

In the alternative embodiment, the support pillar structures 20 may be formed in the support openings 19 at the same time as the memory opening fill structures 58 are formed in the memory openings 49. In this case, the support pillar structures 20 comprise the same materials as the memory opening fill structures 58.

An anneal process can be performed to activate electrical dopants in the drain region 63 and in the vertical semiconductor channel 60. In this case, any amorphous semiconductor material in the vertical semiconductor channel 60 is converted into a polycrystalline semiconductor material. In one embodiment, grains within the vertical semiconductor channel 60 may extend predominantly along a respective local direction that is perpendicular to a respective proximal portion of an inner sidewall of the vertical semiconductor channel 60 and perpendicular to a respective proximal portion of an outer sidewall of the vertical semiconductor channel 60. As used herein, the grains extend predominantly along a specific direction if more than 50% of the drains extend along the specific direction.

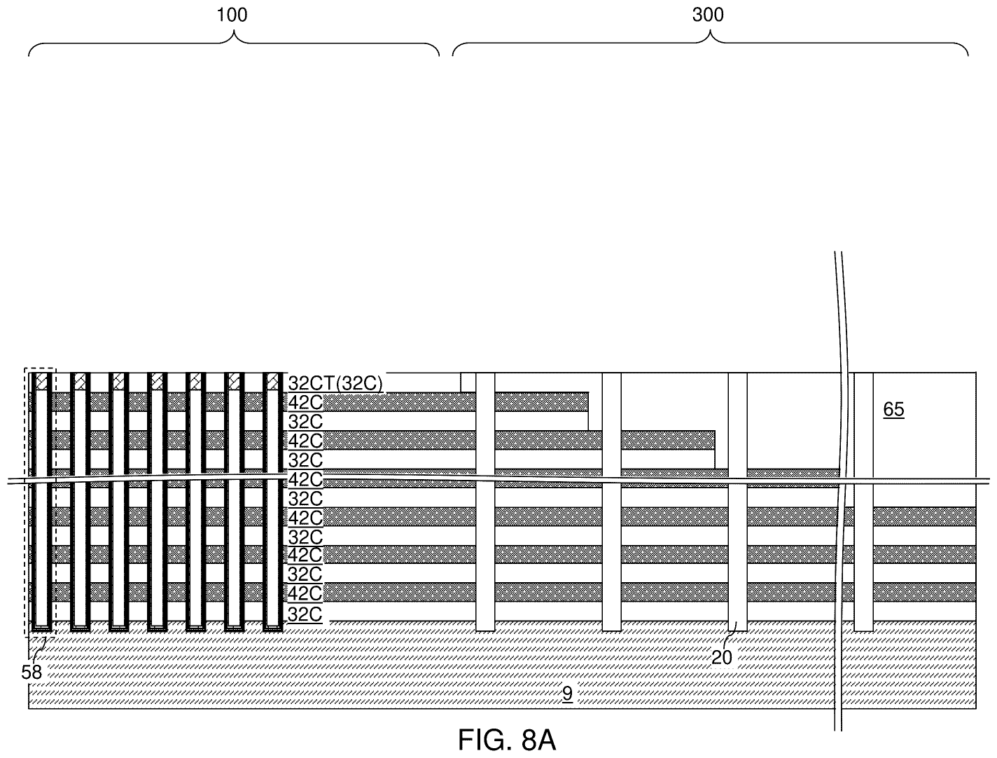

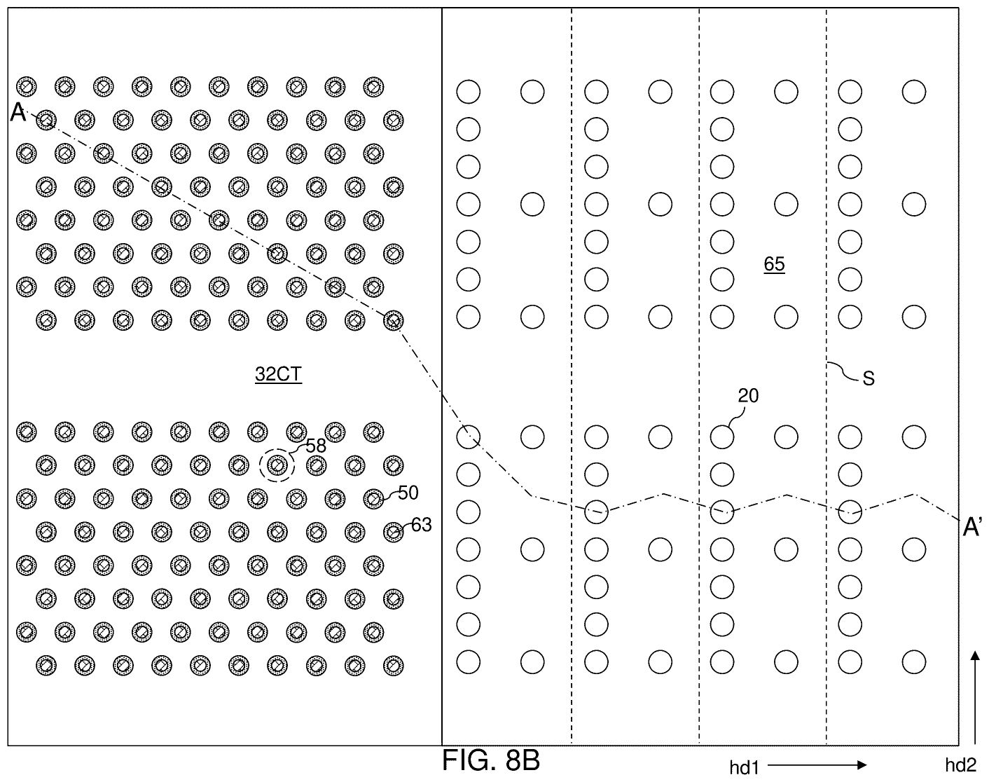

Referring to FIGS. 8A and 8B, the exemplary structure is illustrated after formation of memory opening fill structures 58 within the memory openings 49. The memory opening fill structures 58 are located in the memory openings 49. Each of the memory opening fill structures 58 comprises a respective memory film 50 and a respective vertical semiconductor channel 60.

Thus, a vertically alternating sequence (32C, 42C) of continuous insulating layers 32C and continuous sacrificial material layers 42C is formed over a substrate (such as a carrier substrate 9). The spacer material layers are formed as or are subsequently replaced with electrically conductive layers. Memory openings 49 are formed through the vertically alternating sequence (32C, 42C). Memory opening fill structures 58 are formed in the memory openings 49. Each of the memory opening fill structures 58 comprises a respective memory film 50 and a respective vertical semiconductor channel 60 that is laterally surrounded by the respective memory film 50. The memory opening fill structures 58 are arranged in rows laterally extending along a first horizontal direction hd1, and the rows are laterally spaced apart from each other along a second horizontal direction hd2 that is perpendicular to the first horizontal direction hd1. Each of the memory opening fill structures 58 comprises a vertical stack of memory elements (which may comprise portions of a memory film 50 located at levels of the continuous sacrificial material layers 42C), and a respective drain region 63.

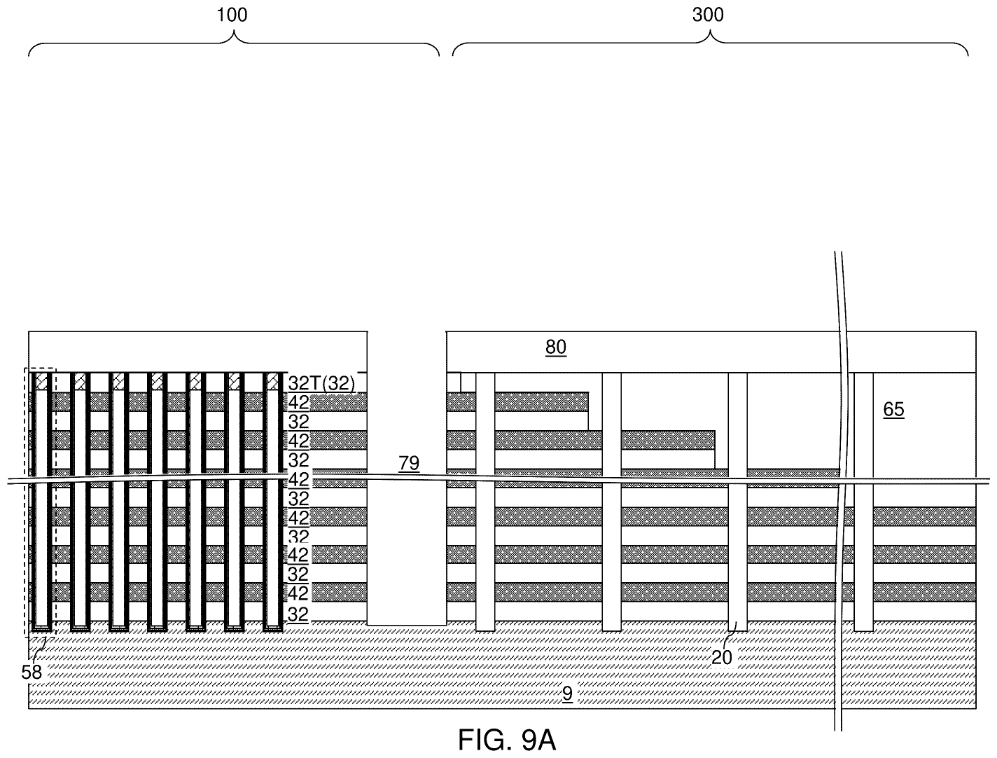

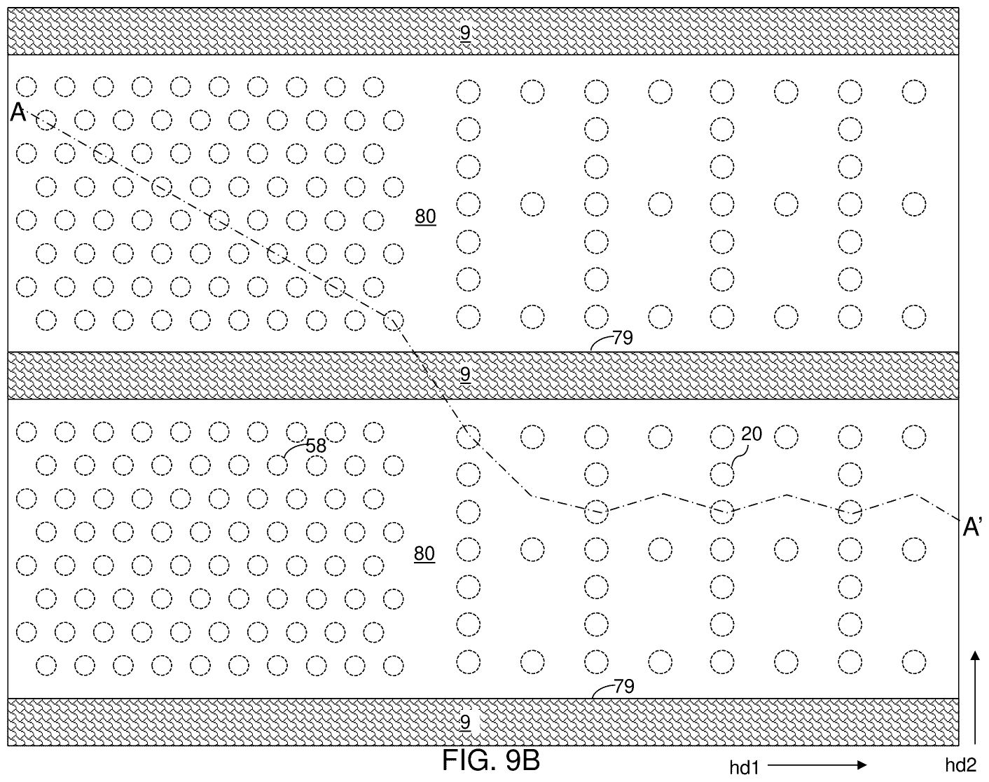

Referring to FIGS. 9A and 9B, a continuous contact-level dielectric layer can be formed over the vertically alternating sequence (32C, 42C), the memory opening fill structures 58, and the retro-stepped dielectric material portion 65. The continuous contact-level dielectric layer comprises a dielectric material, such as a silicate glass material. For example, the contact-level dielectric layer 80 may comprise, and/or may consist essentially of, undoped silicate glass (i.e., silicon oxide) or a doped silicate glass. The thickness of the continuous contact-level dielectric layer 80 may be in a range from 100 nm to 600 nm, such as from 200 nm to 400 nm, although lesser and greater thicknesses may also be employed.

A photoresist layer (not shown) can be applied over the continuous contact-level dielectric layer 80, and can be lithographically patterned to form elongated openings that laterally extend along the first horizontal direction hd1 between neighboring clusters of memory opening fill structures 58. An anisotropic etch process can be performed to transfer the pattern of the openings in the photoresist layer through the contact-level dielectric layer 80, the vertically alternating sequence (32C, 42C), and the retro-stepped dielectric material portion 65, and to a top surface of the carrier substrate 9.

Lateral isolation trenches 79 laterally extending along the first horizontal direction hd1 can be formed through the vertically alternating sequence (32C, 42C), the retro-stepped dielectric material portion 65, and the continuous contact-level dielectric layer. Each of the lateral isolation trenches 79 may comprise a respective pair of lengthwise sidewalls that are parallel to the first horizontal direction hd1 and vertically extend from the top surface of the continuous contact-level dielectric layer to the top surface of the carrier substrate 9. A surface of the carrier substrate 9 can be physically exposed underneath each lateral isolation trench 79. The photoresist layer can be subsequently removed, for example, by ashing.

The anisotropic etch process divides the continuous contact-level dielectric layer into a plurality of contact-level dielectric layers 80 that are laterally spaced apart from each other by the lateral isolation trenches 79. The vertically alternating sequence (32C, 42C) of continuous insulating layers 32C and continuous sacrificial material layers 42C is divided into a plurality of alternating stacks of respective patterned portions of the continuous insulating layers 32C and respective patterned portions of the continuous sacrificial material layers 42C. Each patterned portion of the continuous insulating layers 32C is hereafter referred to as an insulating layer 32. Each patterned portion of the continuous sacrificial material layers 42C is hereafter referred to as a sacrificial material layer 42.

Thus, the lateral isolation trenches 79 are formed through the vertically alternating sequence (32C, 42C), and patterned portions of the vertically alternating sequence (32C, 42C) comprise the plurality of alternating stacks (32, 42). Each contact-level dielectric layer 80 overlies a respective one of the alternating stacks (32, 42). The alternating stacks (32, 42) are laterally spaced apart from each other by lateral isolation trenches 79 that laterally extend along a first horizontal direction hd1. The contact-level dielectric layers 80 are laterally spaced apart from each other by the lateral isolation trenches 79. Top edges of the lateral isolation trenches 79 are located within a horizontal plane including top surfaces of the contact-level dielectric layers 80.

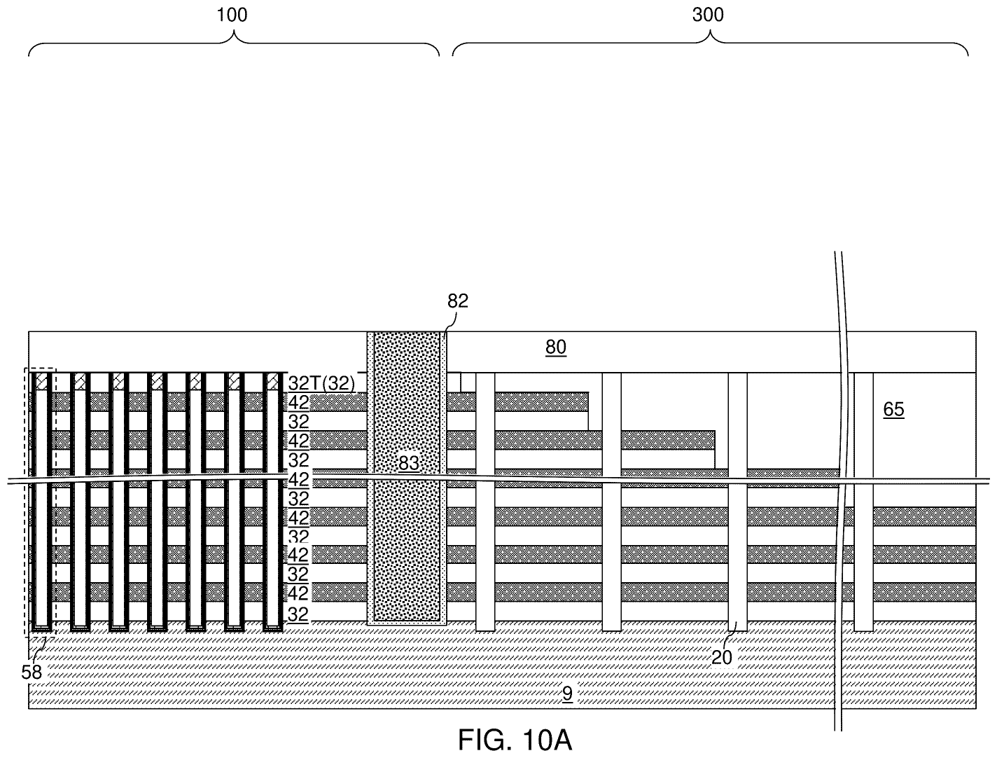

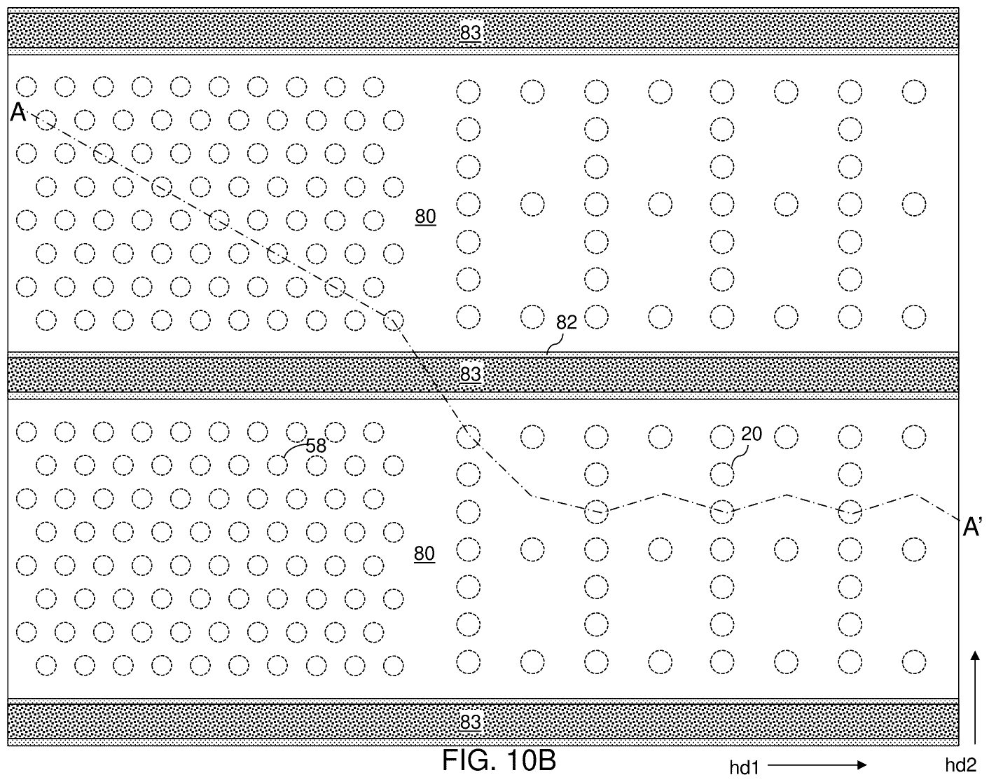

Referring to FIGS. 10A and 10B, an optional sacrificial liner 82 can be optionally conformally deposited on all physically exposed surfaces around the lateral isolation trenches 79 and over the contact-level dielectric layers 80. The sacrificial liner 82 comprises a thin sacrificial material that may be subsequently removed by performing an isotropic etch process. The sacrificial liner 82 may comprise silicon oxide, silicon nitride, a dielectric metal oxide, or a combination thereof, and may have a thickness in a range from 1 nm to 10 nm, such as from 2 nm to 6 nm, although lesser and greater thicknesses may also be employed.

A sacrificial fill material that may be removed selectively to the material of the sacrificial liner 82 may be deposited in remaining volumes of the lateral isolation trenches 79. If the sacrificial fill material can be subsequently removed selectively to the materials of the carrier substrate 9, the insulating layers 32, the sacrificial material layers 42, and the retro-stepped dielectric material portion 65, then the sacrificial liner 82 may be omitted. In an illustrative example, the sacrificial fill material may comprise a carbon-based material such as amorphous carbon or diamond-like carbon, a polymer material, or a semiconductor material such as amorphous silicon or a silicon-germanium. Excess portions of the sacrificial fill material can be removed from above the horizontal plane including the top surfaces of the contact-level dielectric layers 80 by performing a planarization process, such as a chemical mechanical polishing process. Each remaining portion of the sacrificial fill material that fills a respective lateral isolation trench 79 comprises a sacrificial lateral isolation trench fill structure 83. Horizontally-extending portions of the sacrificial liner 82 may be removed from above the horizontal plane including the top surfaces of the contact-level dielectric layer 80. Thus, each volume of the lateral isolation trenches 79 may be filled with a sacrificial lateral isolation trench fill structure 83 and optionally with a sacrificial liner 82. In one embodiment, top surfaces of the sacrificial lateral isolation trench fill structures 83 and the optional sacrificial liners 82 may be coplanar with the top surfaces of the contact-level dielectric layers 80.

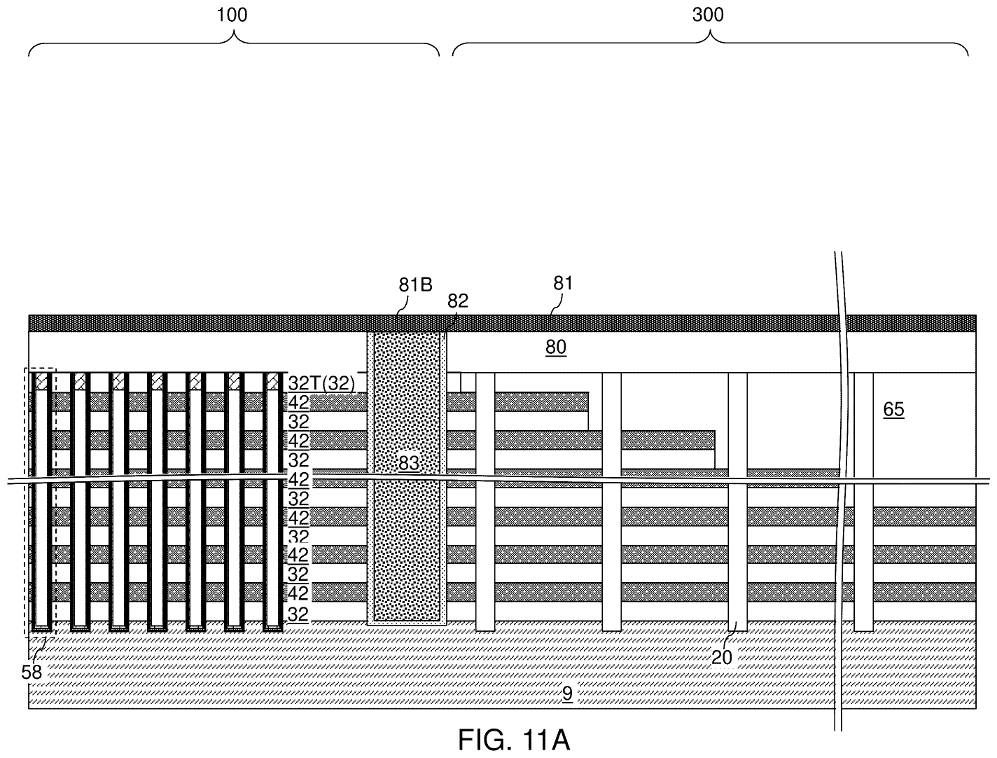

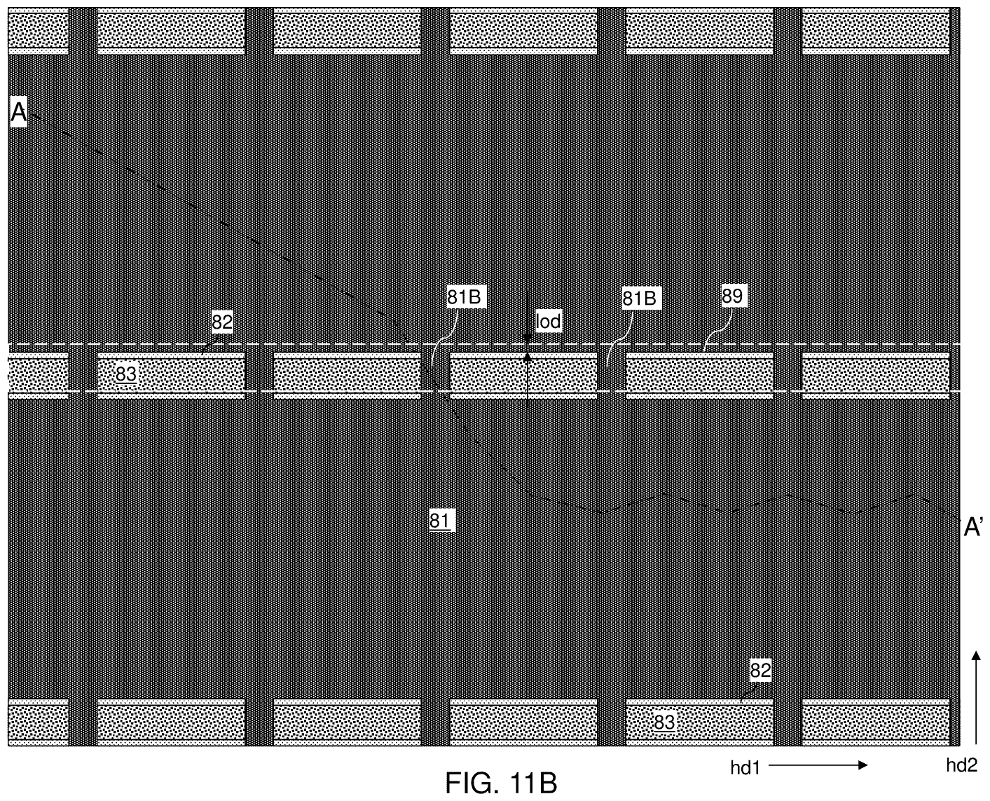

Referring to FIGS. 11A and 11B, a dielectric material that will be used to form the perforated dielectric bridge layer 81 can be deposited over the contact-level dielectric layers 80 and the sacrificial lateral isolation trench fill structures 83. The dielectric material has a high etch resistance to etchants, such as hydrofluoric acid that is used to etch silicon oxide of the contact-level dielectric layers 80 and the retro-stepped dielectric material portion 65, and phosphoric acid that is used to etch silicon nitride of the sacrificial material layers 42, respectively. In one embodiment, the dielectric material may be used as a polish stop material, and may have a higher Young's modulus than the dielectric materials of the contact-level dielectric layers 80 and the insulating layers 32 to increase its deformation resistance during one or more subsequent processing steps. In one embodiment, the contact-level dielectric layers 80 and the insulating layers 32 may comprise silicate glass materials (e.g., silicon dioxide) having Young's moduli in a range from 60 GPa to 75 GPa, and the dielectric material that is deposited over the contact-level dielectric layers 80 and the sacrificial lateral isolation trench fill structures 83 may have a Young's modulus that is greater than 80 GPa, such as 100 to 400 GPa, including 100 to 230 GPa. A blanket dielectric material layer is deposited, which is subsequently employed to form a perforated dielectric bridge layer, i.e., a dielectric layer including perforations in a manner that provides bridge portions. As used herein, a “blanket” layer refers to a layer that does not contain any perforation therethrough.

Generally, the contact-level dielectric layers 80 comprise a first dielectric material having a first Young's modulus, and the deposited blanket dielectric material layer comprises a second dielectric material that is different from the first dielectric material and having a second Young's modulus that is greater than the first Young's modulus. In one embodiment the first dielectric material comprises a silicate glass material and the first Young's modulus may be in a range from 60 GPa to 75 GPa; and the second dielectric material comprises a material selected from silicon carbonitride, silicon oxycarbide, or a dielectric metal oxide. The second Young's modulus may be greater than 80 GPa, and preferably greater than 100 GPa, and more preferably greater than 150 GPa. Silicon carbonitride has a Young's modulus in a range from 180 GPa to 230 GPa, silicon oxycarbide has a Young's modulus in a range from 120 GPa to 160 GPa, and dielectric metal oxides have a respective Young's modulus in a range from 100 GPa to 400 GPa. The thickness of the blanket dielectric material layer may be in a range from 50 nm to 500 nm, such as from 100 nm to 300 nm, although lesser and greater thicknesses may also be employed.

A photoresist layer (not shown) can be applied over the blanket dielectric material layer, and can be lithographically patterned to form rows of elongated openings over the sacrificial lateral isolation trench fill structures 83. Each row of elongated openings in the photoresist layer can be formed over a respective sacrificial lateral isolation trench fill structures 83. The elongated openings may be elongated along the first horizontal direction (e.g., word line direction) hd1, i.e., the lengthwise direction of the lateral isolation trenches 79. Further, the elongated openings within each row of elongated openings may be laterally spaced apart along the first horizontal direction hd1. The width of each elongated opening along the second horizontal direction hd2 may be the same as, or may be different from, the width of a respective underlying lateral isolation trench 79. In one embodiment, the width of each elongated opening along the second horizontal direction hd2 may be in a range from 60% of the width of the respective underlying lateral isolation trench 79 to 200% of the width of the respective underlying lateral isolation trench 79. Further, each row of elongated openings in the photoresist layer may optionally be laterally offset from the underlying lateral isolation trench 79 by an overlay error, which may be greater than zero and less than about 50 nm depending on the lithographic tool employed to pattern the rows of elongated openings in the photoresist layer.

An anisotropic etch process can be performed to transfer the pattern of the rows of elongated openings in the photoresist layer through the blanket dielectric material layer. Rows of elongated openings 89 are formed through the blanket dielectric material layer. Thus, the blanket dielectric material layer is converted into a perforated dielectric bridge layer 81. The photoresist layer may be subsequently removed, for example, by ashing.

Generally, the perforated dielectric bridge layer 81 can be formed over the plurality of alternating stacks (32, 42) and sacrificial lateral isolation trench fill structures 83 as a single contiguous material layer. Thus, the perforated dielectric bridge layer 81 laterally extends over each of the alternating stacks (32, 42) and each of the lateral isolation trenches 79. The perforated dielectric bridge layer 81 comprises rows of elongated openings 89 therethrough. Each row of elongated openings 89 overlies a respective one of the sacrificial lateral isolation trench fill structures 83 and is arranged along the first horizontal direction hd1. Neighboring pairs of elongated openings 89 within each row of elongated openings 89 are laterally spaced by bridge portions 81B of the perforated dielectric bridge layer 81 that extend over a respective one of the lateral isolation trenches 79. In one embodiment, the rows of elongated openings 89 may be arranged as a two-dimensional periodic array of elongated openings 89. In one embodiment, each of the elongated openings 89 may have a shape of a rectangle or a rounded rectangle in a plan view.

In one embodiment, each row of elongated openings 89 that overlies the respective one of the lateral isolation trenches 79 comprises lengthwise opening sidewalls laterally extending along the first horizontal direction hd1 and widthwise opening sidewalls laterally extending along the second horizontal direction hd2. Generally, the lengthwise opening sidewalls may optionally be vertically coincident with (i.e., contained within a same vertical plane as) a lengthwise sidewall of an underlying lateral isolation trench 79. In some embodiments, the lengthwise opening sidewalls of the elongated openings 89 within a row of elongated openings 89 may be laterally offset from a most proximal lengthwise sidewall of the respective one of the lateral isolation trenches 79 by a lateral offset distance “lod” along a second horizontal direction hd2 that is perpendicular to the first horizontal direction hd1. The lateral offset distance “lod” may be in a range from 0 nm to 100 nm, such as from 10 nm to 50 nm, although lesser and greater lateral offset distances lod may also be employed.

In one embodiment, each of the elongated openings 89 has a respective first lateral extent along the first horizontal direction hd1 and a respective second lateral extent along the second horizontal direction hd2. The ratio of the respective first lateral extent to the respective second lateral extent may be in a range from 2 to 30, such as from 4 to 12, although lesser and greater ratios may also be employed. The lateral extent (i.e., the width) of each elongated opening 89 along the second horizontal direction hd2 (i.e., the second lateral extent) may be in a range from 60% of the width of a respective underlying lateral isolation trench 79 to 200% of the width of the respective underlying lateral isolation trench 79.

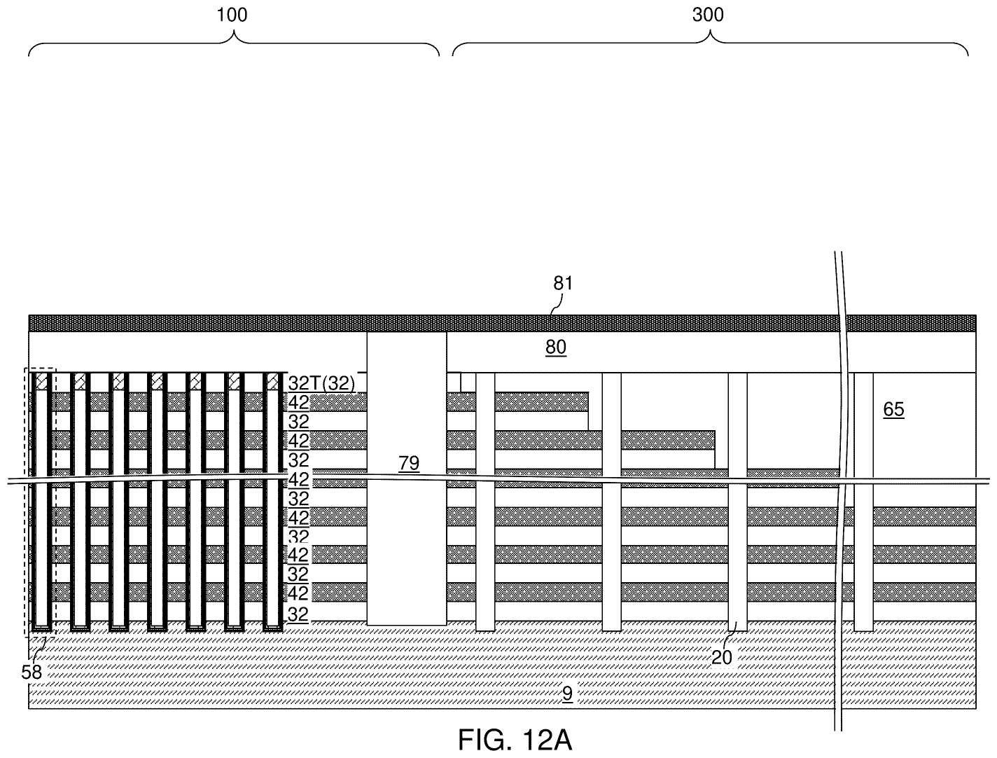

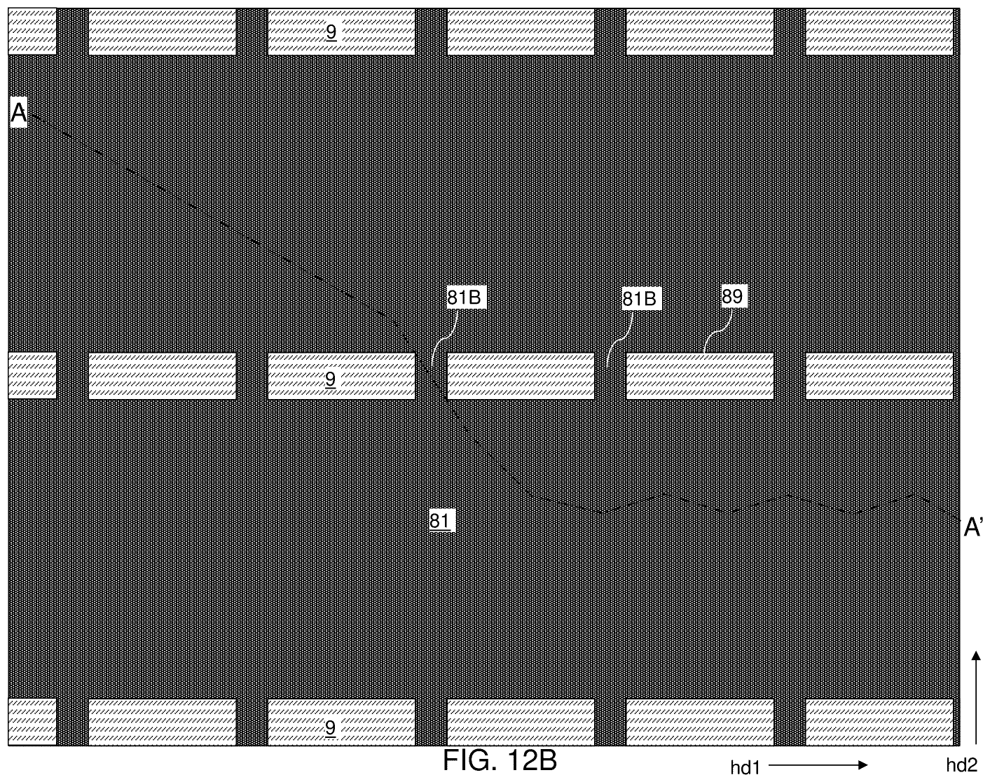

Referring to FIGS. 12A and 12B, the sacrificial lateral isolation trench fill structures 83 and the optional sacrificial liners 82 may be selectively removed without significantly etching the materials of the perforated dielectric bridge layer 81, the contact-level dielectric layers 80, the insulating layers 32, the sacrificial material layers 42, and the carrier substrate 9. For example, if the sacrificial lateral isolation trench fill structures 83 comprise a carbon-based material, the sacrificial lateral isolation trench fill structures 83 may be removed by performing an ashing process. If the sacrificial lateral isolation trench fill structures 83 comprise a semiconductor material such as amorphous silicon, a wet etch process using hot trimethyl-2 hydroxyethyl ammonium hydroxide (“hot TMY”) or tetramethyl ammonium hydroxide (TMAH) may be performed to isotropically etch the sacrificial lateral isolation trench fill structures 83. The sacrificial liners 82 may be removed by performing a suitable isotropic etch process that does not significantly etch the materials of the perforated dielectric bridge layer 81, the contact-level dielectric layers 80, the insulating layers 32, the sacrificial material layers 42, and the carrier substrate 9 significantly. Generally, the sacrificial lateral isolation trench fill structures 83 are removed without removing the plurality of alternating stacks (32, 42) or the perforated dielectric bridge layer 81. Voids are formed in the volumes of the lateral isolation trenches 79. The voids within the volumes of the lateral isolation trenches 79 are connected to the ambient through the rows of elongated openings 89 in the perforated dielectric bridge layer 81.

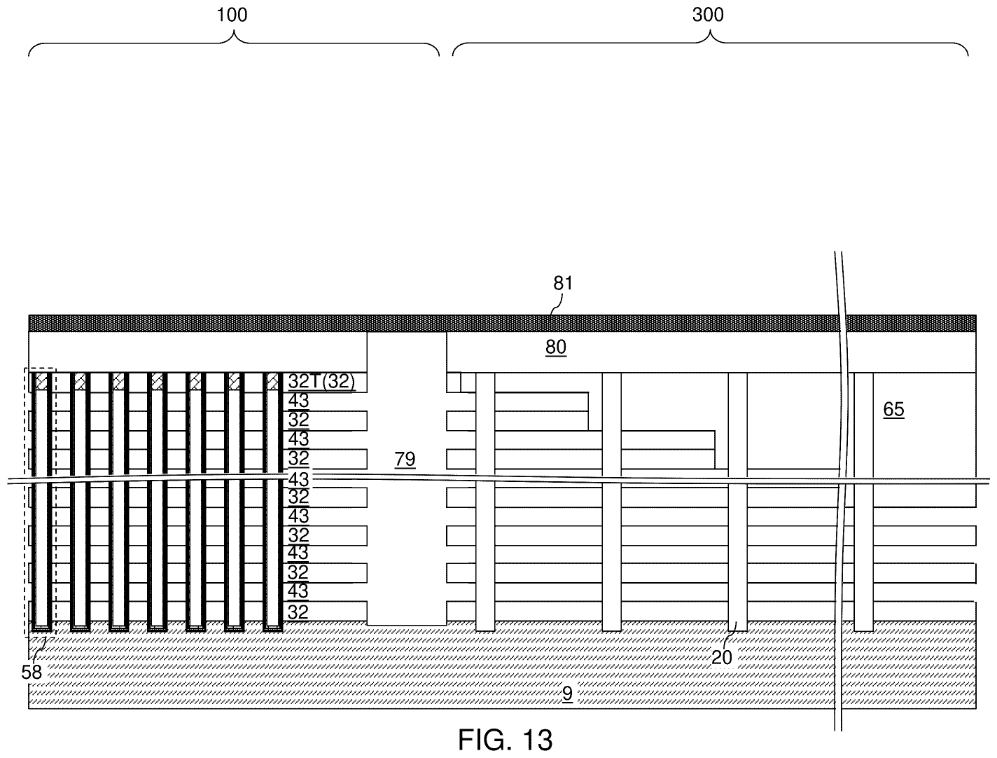

Referring to FIG. 13, an etchant that selectively etches the material of the sacrificial material layers 42 with respect to the material of the insulating layers 32, the contact-level dielectric layer 80, the perforated dielectric bridge layer 81, and the retro-stepped dielectric material portion 65 can be introduced into the lateral isolation trenches 79, for example, employing an isotropic etch process. Lateral recesses 43 are formed in volumes from which the sacrificial material layers 42 are removed. The removal of the sacrificial material layers 42 can be selectively to the materials of the insulating layers 32, the contact-level dielectric layer 80, the retro-stepped dielectric material portion 65, and the material of the outermost layer of the memory films 50. In one embodiment, the sacrificial material layers 42 can include silicon nitride, and the materials of the insulating layers 32 and the retro-stepped dielectric material portion 65 can include silicon oxide.

The etch process that removes the second material selectively to the first material and the outermost layer of the memory films 50 can be a wet etch process employing a wet etch solution, or can be a gas phase (dry) etch process in which the etchant is introduced in a vapor phase into the lateral isolation trenches 79. For example, if the sacrificial material layers 42 include silicon nitride, the etch process can be a wet etch process in which the exemplary structure is immersed within a wet etch tank including phosphoric acid, which etches silicon nitride selectively to silicon oxide, silicon, and various other materials employed in the art. Generally, the lateral recesses 43 can be formed by performing an isotropic etch process that etches the sacrificial material layers 42 without etching the insulating layers 32 or the perforated dielectric bridge layer 81. The support pillar structure 20, the retro-stepped dielectric material portion 65, and the memory stack structures 55 provide structural support while the lateral recesses 43 are present within volumes previously occupied by the sacrificial material layers 42.

Each lateral recess 43 can be a laterally extending cavity having a lateral dimension that is greater than the vertical extent of the cavity. In other words, the lateral dimension of each lateral recess 43 can be greater than the height of the lateral recess 43. A plurality of lateral recesses 43 can be formed in the volumes from which the second material of the sacrificial material layers 42 is removed. Each of the plurality of lateral recesses 43 can extend substantially parallel to the top surface of the carrier substrate 9. A lateral recess 43 can be vertically bounded by a top surface of an underlying insulating layer 32 and a bottom surface of an overlying insulating layer 32. In one embodiment, each lateral recess 43 can have a uniform height throughout.

According to an aspect of the present disclosure, the perforated dielectric bridge layer 81 provides structural support between neighboring pairs of contiguous material portions each including a vertical stack of insulating layers 32, a set of support pillar structures 20, a set of memory opening fill structures 58, and a contact-level dielectric layer 80 during formation of the lateral recesses 43 and during formation of electrically conductive layers within the lateral recesses 43. Removal of the sacrificial material layers 42 generates an increased mechanical stress on the insulating layers 32 and the contact-level dielectric layers 80 that may cause lateral tilting of the insulating layers 32 and the contact-level dielectric layers 80 into the lateral isolation trenches 79. This results in widening of a subset of the lateral isolation trenches 79 and narrowing of another subset of the lateral isolation trenches 79. The perforated dielectric bridge layer 81 (i.e., the bridge portions 81B) function as a stiffener structures that prevent or reduce lateral deformation of the various structural components during replacement of the sacrificial material layers 42 with electrically conductive layers.

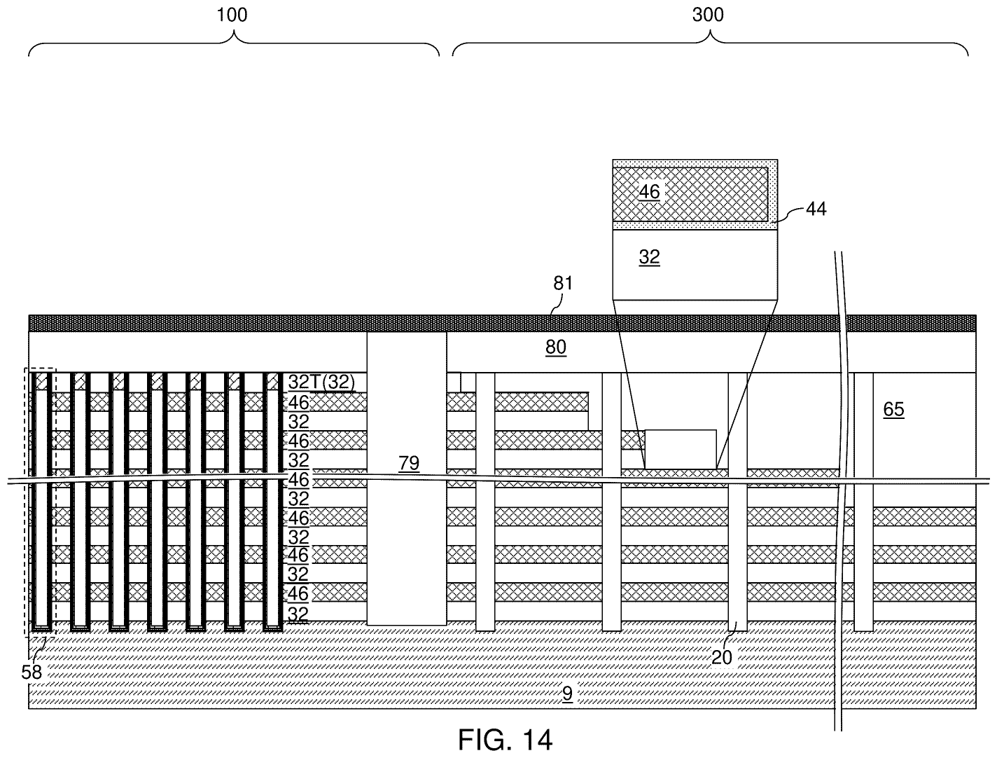

Referring to FIG. 14, an outer blocking dielectric layer 44 can be optionally formed. The outer blocking dielectric layer, if present, comprises a dielectric material that functions as a control gate dielectric for the control gates to be subsequently formed in the lateral recesses 43. In case the blocking dielectric layer 52 is present within each memory opening, the outer blocking dielectric layer is optional. In case the blocking dielectric layer 52 is omitted, the outer blocking dielectric layer is present.

At least one conductive material can be deposited in the lateral recesses 43 by providing at least one reactant gas into the lateral recesses 43 through the lateral isolation trenches 79. A metallic barrier layer can be deposited in the lateral recesses 43. The metallic barrier layer includes an electrically conductive metallic material that can function as a diffusion barrier layer and/or adhesion promotion layer for a metallic fill material to be subsequently deposited. The metallic barrier layer can include a conductive metallic nitride material such as TiN, TaN, WN, or a stack thereof, or can include a conductive metallic carbide material such as TiC, TaC, WC, or a stack thereof. In one embodiment, the metallic barrier layer can be deposited by a conformal deposition process such as chemical vapor deposition (CVD) or atomic layer deposition (ALD). The thickness of the metallic barrier layer can be in a range from 2 nm to 8 nm, such as from 3 nm to 6 nm, although lesser and greater thicknesses can also be employed. In one embodiment, the metallic barrier layer can consist essentially of a conductive metal nitride such as TiN.

A metal fill material is deposited in the plurality of lateral recesses 43, on the sidewalls of each lateral isolation trench 79, and over the top surface of the contact-level dielectric layer 80 to form a metallic fill material layer. The metallic fill material can be deposited by a conformal deposition method, which can be, for example, chemical vapor deposition (CVD), atomic layer deposition (ALD), electroless plating, electroplating, or a combination thereof. In one embodiment, the metallic fill material layer can consist essentially of at least one elemental metal. The at least one elemental metal of the metallic fill material layer can be selected, for example, from tungsten, cobalt, ruthenium, titanium, and tantalum. In one embodiment, the metallic fill material layer can consist essentially of a single elemental metal. In one embodiment, the metallic fill material layer can be deposited employing a fluorine-containing precursor gas such as WF₆. In one embodiment, the metallic fill material layer can be a tungsten layer including a residual level of fluorine atoms as impurities. The metallic fill material layer is spaced from the insulating layers 32 and the memory stack structures 55 by the metallic barrier layer, which is a metallic barrier layer that blocks diffusion of fluorine atoms therethrough.

Generally, electrically conductive layers 46 are formed within the volumes of the lateral recesses 43 by performing a conformal deposition process during which the lateral isolation trenches 79 are employed as conduits for providing a reactant that forms the electrically conductive layers 46 upon decomposition. A plurality of electrically conductive layers 46 can be formed in the plurality of lateral recesses 43, and a continuous metallic material layer can be formed on the sidewalls of each lateral isolation trench 79 and over the contact-level dielectric layer 80. Each electrically conductive layer 46 includes a portion of the metallic barrier layer and a portion of the metallic fill material layer that are located between a vertically neighboring pair of dielectric material layers such as a pair of insulating layers 32. The continuous metallic material layer includes a continuous portion of the metallic barrier layer and a continuous portion of the metallic fill material layer that are located in the lateral isolation trenches 79 or above the contact-level dielectric layer 80.

The deposited metallic material of the continuous electrically conductive material layer is etched back from the sidewalls of each lateral isolation trench 79 and from above the contact-level dielectric layer 80 by performing an isotropic etch process that etches the at least one conductive material of the continuous electrically conductive material layer. Each remaining portion of the deposited metallic material in the lateral recesses 43 constitutes an electrically conductive layer 46. Each electrically conductive layer 46 can be a conductive line structure. Thus, the sacrificial material layers 42 are replaced with the electrically conductive layers 46. Generally, the electrically conductive layers 46 can be formed by providing a metallic precursor gas into the lateral isolation trenches 79 and into the lateral recesses 43.

Each electrically conductive layer 46 may be embedded within a respective outer blocking dielectric layer 44, which may comprise a dielectric metal oxide material, such as aluminum oxide. Each outer blocking dielectric layer 44 may have a pair of horizontally-extending portions in contact with a respective one of the insulating layers 32, and a plurality of tubular portions laterally surrounding a respective one of the memory opening fill structures 58 and connecting the pair of horizontally-extending portions. The thickness of each outer blocking dielectric layer 44 may be in a range from 1 nm to 6 nm, although lesser and greater thicknesses may also be employed. The sacrificial material layers 42 are replaced with material portions comprising electrically conductive layers 46.

Generally, an assembly of an alternating stack (32, 46) and memory opening fill structures 58 can be formed. The alternating stack (32, 46) comprises a vertically alternating sequence of insulating layers 32 and electrically conductive layers 46. The memory opening fill structures 58 vertically extend through the alternating stack (32, 46). Each of the memory opening fill structures 58 comprises a respective vertical stack of memory elements (which may comprise portions of a memory material layer 54 located at levels of the electrically conductive layers 46), a respective vertical semiconductor channel 60, and a respective drain region 63. At least one uppermost electrically conductive layer 46 may comprise a drain side select gate electrode. At least one bottommost electrically conductive layer 46 may comprise a source side select gate electrode. The remaining electrically conductive layers 46 may comprise word lines. Each word line functions as a common control gate electrode for the plurality of vertical NAND strings (e.g., memory opening fill structures 58).

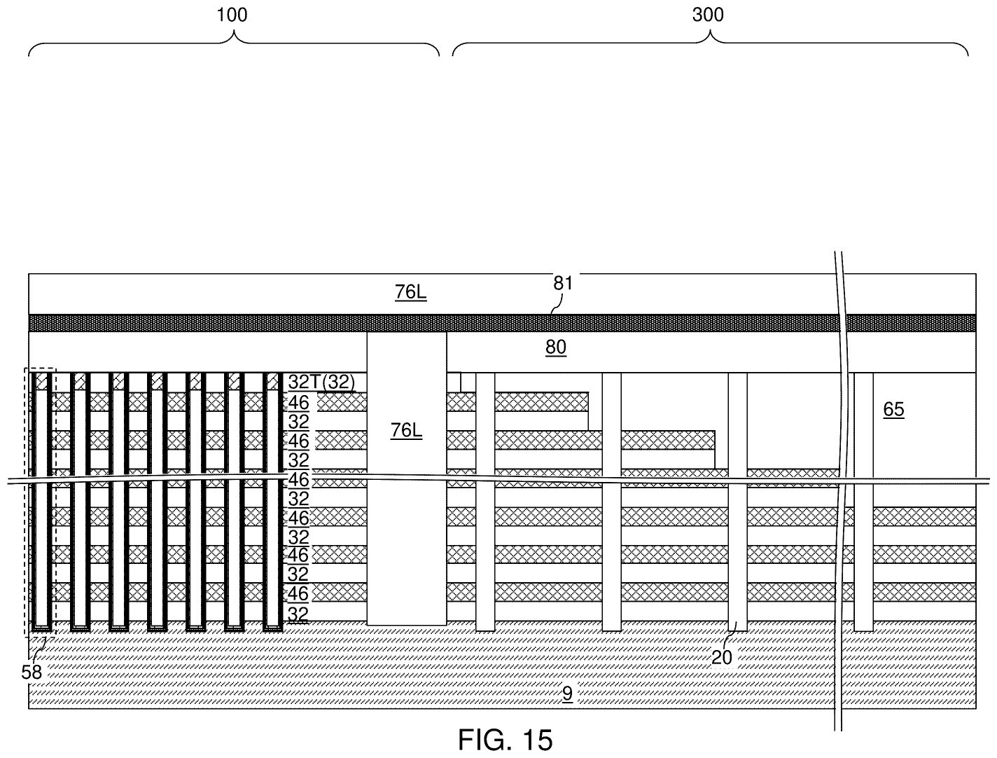

Referring to FIG. 15, a dielectric fill material, such as silicon oxide can be conformally deposited in the volumes of the lateral isolation trenches 79 and the elongated openings 89 through the perforated dielectric bridge layer 81 and over the top surface of the perforated dielectric bridge layer 81. For example, a chemical vapor deposition process may be employed to deposit the dielectric fill material. The duration of the deposition process that deposits the dielectric fill material can be selected such that the lateral isolation trenches 79 and the elongated openings 89 are completely filled with the deposited dielectric fill material. A dielectric fill material layer 76L can be formed, which fills the volumes of the lateral isolation trenches 79 and the elongated openings 89 through the perforated dielectric bridge layer 81, and comprises a horizontally-extending portion that overlies the top surface of the perforated dielectric bridge layer 81.

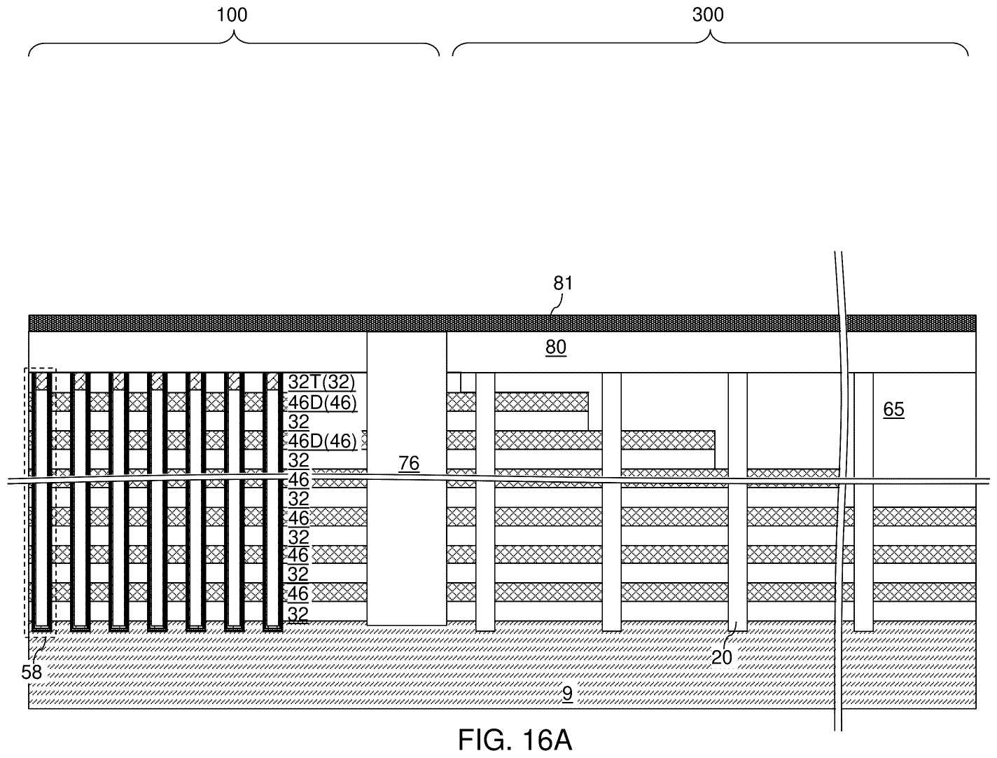

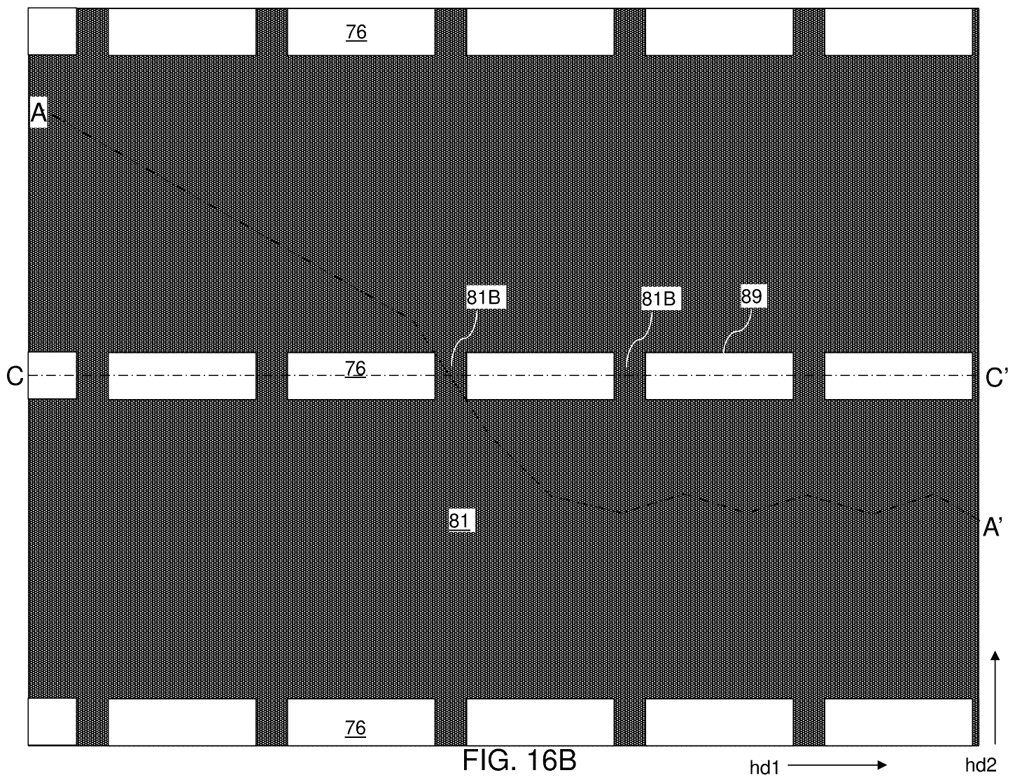

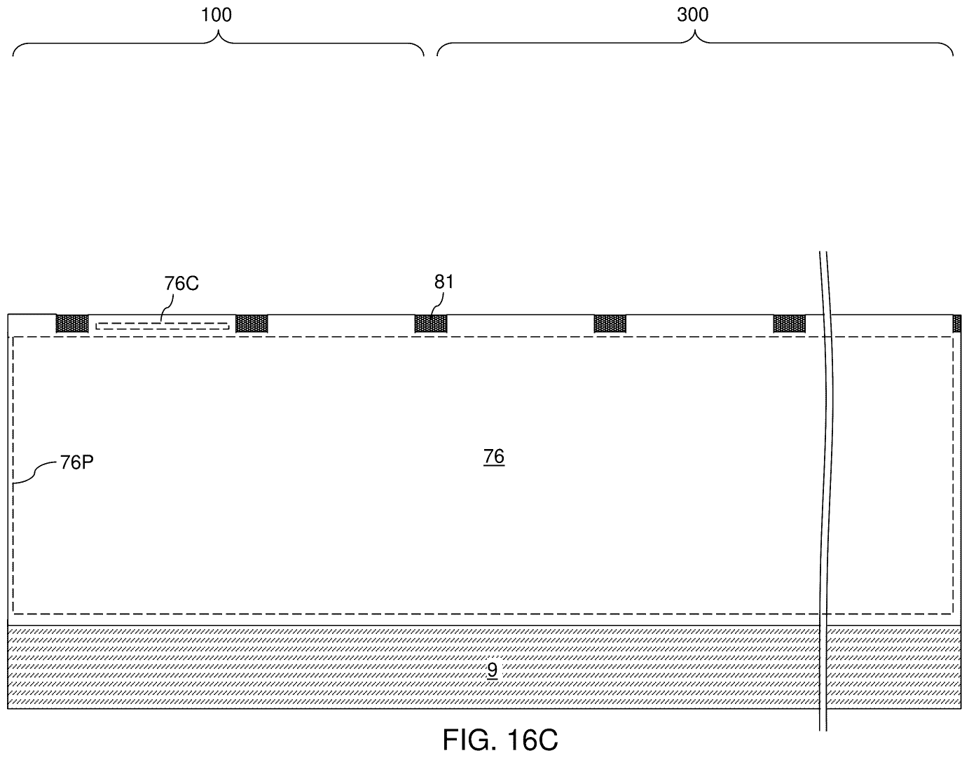

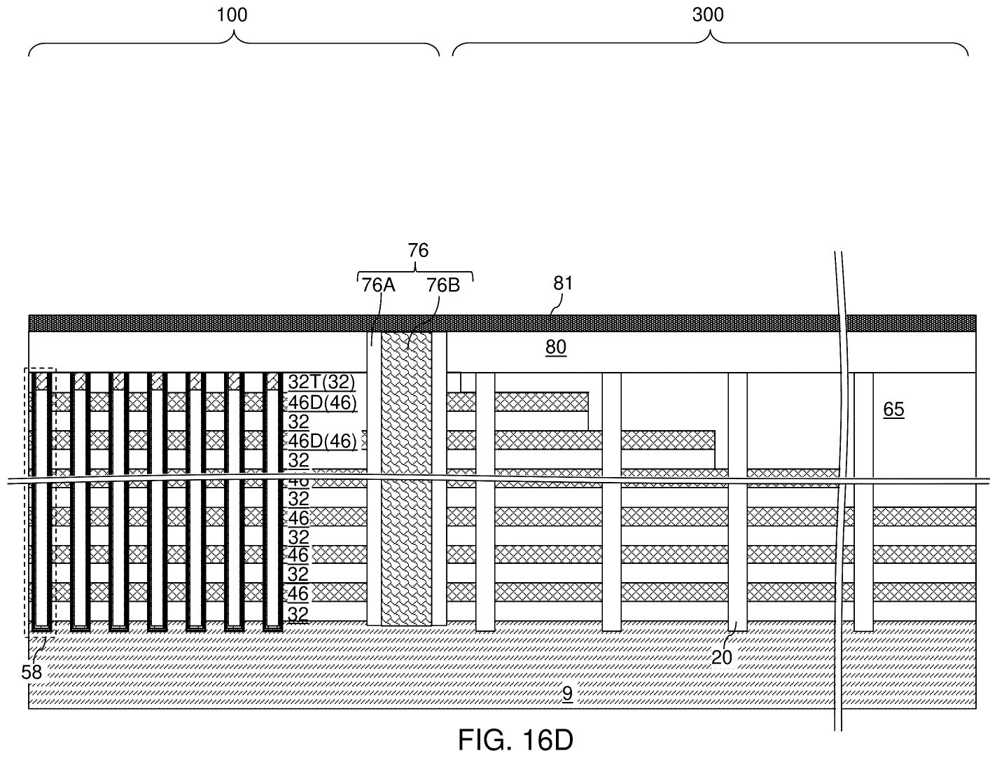

Referring to FIG. 16A-16C, portions of the dielectric fill material layer 76L that overlie the horizontal plane including the top surface of the perforated dielectric bridge layer 81 can be removed by performing a planarization process. The planarization process may comprise a recess etch process and/or a chemical mechanical polishing process. The perforated dielectric bridge layer 81 functions as an etch stop or a polish stop layer during the planarization process. Each remaining portion of the dielectric fill material that fills a respective continuous volume including a volume of a lateral isolation trench 79 and an overlying row of elongated openings 89 through the perforated dielectric bridge layer 81 constitutes a lateral isolation wall structure 76, which may be a dielectric wall structure that provides lateral electrical isolation between a neighboring pair of alternating stacks (32, 42).

In an alternative embodiment shown in FIG. 16D, a combination of a dielectric liner material and at least one electrically conductive fill material (which may comprise a heavily doped semiconductor material or a metallic material) may be deposited in lieu of the dielectric fill material layer 76L. In this case, each continuous volume including a volume of a lateral isolation trench 79 and an overlying row of elongated openings 89 through the perforated dielectric bridge layer 81 may be filled with a lateral isolation wall structure 76 including a surface dielectric material portion (e.g., an insulating sidewall liner) 76A that embeds an electrically conductive local interconnect 76B. Such lateral isolation wall structures may provide the same function of lateral electrical isolation between neighboring pairs of alternating stacks (32, 46) as the lateral isolation wall structure 76 consisting of at least one dielectric fill material.

Generally, the lateral isolation wall structures 76 may be formed by filling volumes of the lateral isolation trenches 79 and the elongated openings 89 in the perforated dielectric bridge layer 81 with at least one dielectric material and optionally with an additional electrically conductive material. Each lateral isolation wall structures 76 fills a lateral isolation trench 79 and a row of elongated openings 89 in the perforated dielectric bridge layer 81.

In one embodiment shown in FIG. 16C, each of the lateral isolation wall structures 76 comprises a primary dielectric wall portion 76P that fills a respective one of the lateral isolation trenches 79 and further comprises a row of castellated protrusions 76C adjoined to the primary dielectric wall portion 76P and that fills a respective row of elongated openings 89 in the perforated dielectric bridge layer 81. In one embodiment, each of the castellated protrusions 76C may have a shape of a rectangular parallelopiped. In one embodiment, top surfaces of the lateral isolation wall structures 76 are formed within a horizontal plane including a top surface of the perforated dielectric bridge layer 81. In one embodiment, the lateral isolation wall structures 76 contact all sidewall surfaces of the elongated openings 89 in the perforated dielectric bridge layer 81.

An alternating stack (32, 46) of insulating layers 32 and electrically conductive layers 46 can be formed in a memory block area between each neighboring pair of lateral isolation wall structures 76. Electrically conductive layers 46 within each alternating stack (32, 46) can include at least one drain-select-level electrically conductive layer 46D (i.e., at least one drain side select gate electrode) which is employed to activate or deactivate NAND strings (e.g., the memory opening fill structures 58 and adjacent portions of the electrically conductive layers 46) from the drain side. A subset of the electrically conductive layers 46 within each alternating stack (32, 46) comprises word lines, which underlie the drain-select-level electrically conductive layers 46D and comprise control electrodes of the NAND strings. Within each alternating stack (32, 46), a subset of one or more bottommost electrically conductive layers 46 which underlies the word lines comprises source side select gate electrodes.

A perforated dielectric bridge layer 81 laterally extends over each of the alternating stacks (32, 46) and each of the lateral isolation trenches 79. The perforated dielectric bridge layer 81 includes rows of elongated openings 89 therethrough. Optionally, the perforated dielectric bridge layer 81 may be etched back to reduce its thickness after the lateral isolation wall structure 76 planarization step. Alternatively, the perforated dielectric bridge layer 81 may be completely removed by selective etching after the lateral isolation wall structure 76 planarization step.

Each row of elongated openings 89 overlies a respective one of the lateral isolation trenches 79 and is arranged along the first horizontal direction hd1. The alternating stacks (32, 46) are laterally spaced apart from each other by lateral isolation trenches 79 that laterally extend along a first horizontal direction hd1. Arrays of memory stack structures 55 are provided. Each array of memory stack structures 55 vertically extends through a respective one of the alternating stacks (32, 46), and each of the memory stack structures 55 comprises a respective vertical semiconductor channel 60 and a vertical stack of memory elements (e.g., portions of the memory film 50) located at levels of the electrically conductive layers 46.

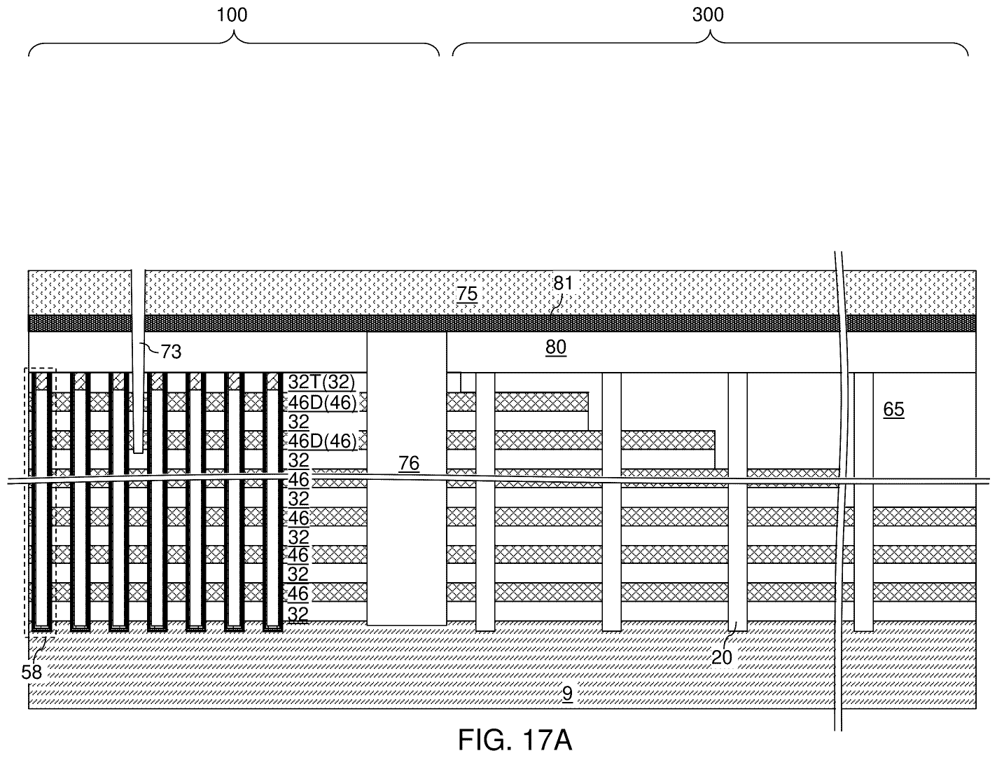

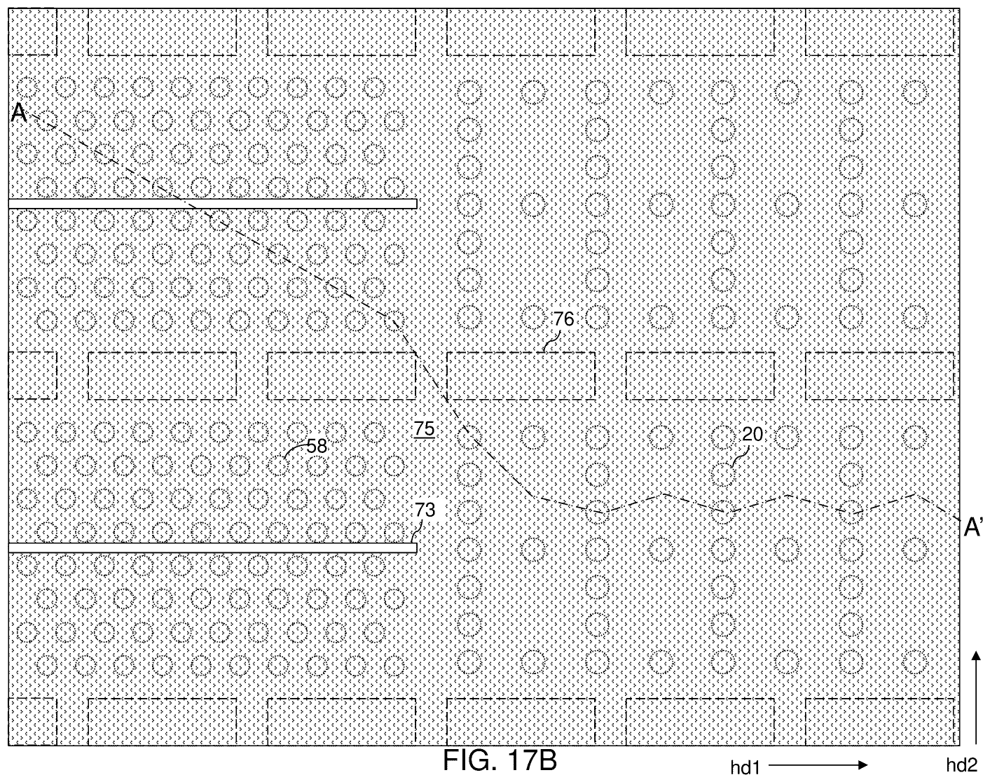

Referring to FIGS. 17A and 17B, drain-select-level isolation trenches 73 can be formed through the drain-select-level electrically conductive layers 46D (i.e., an upper subset of the electrically conductive layers 46 within each alternating stack (32, 46)), for example, by forming a first patterned photoresist layer 75 including elongated openings that laterally extend along the first horizontal direction hd1 over the perforated dielectric bridge layer 81, and by performing an anisotropic etch process that transfers the pattern in the first patterned photoresist layer 75 into underlying material layers comprising the drain-select-level electrically conductive layers 46D. Each of the drain-select-level electrically conductive layers 46D may be divided into a respective plurality of drain-select-level electrically conductive strips (i.e., drain side select gate electrodes). The first patterned photoresist layer 75 can be removed, for example, by ashing.

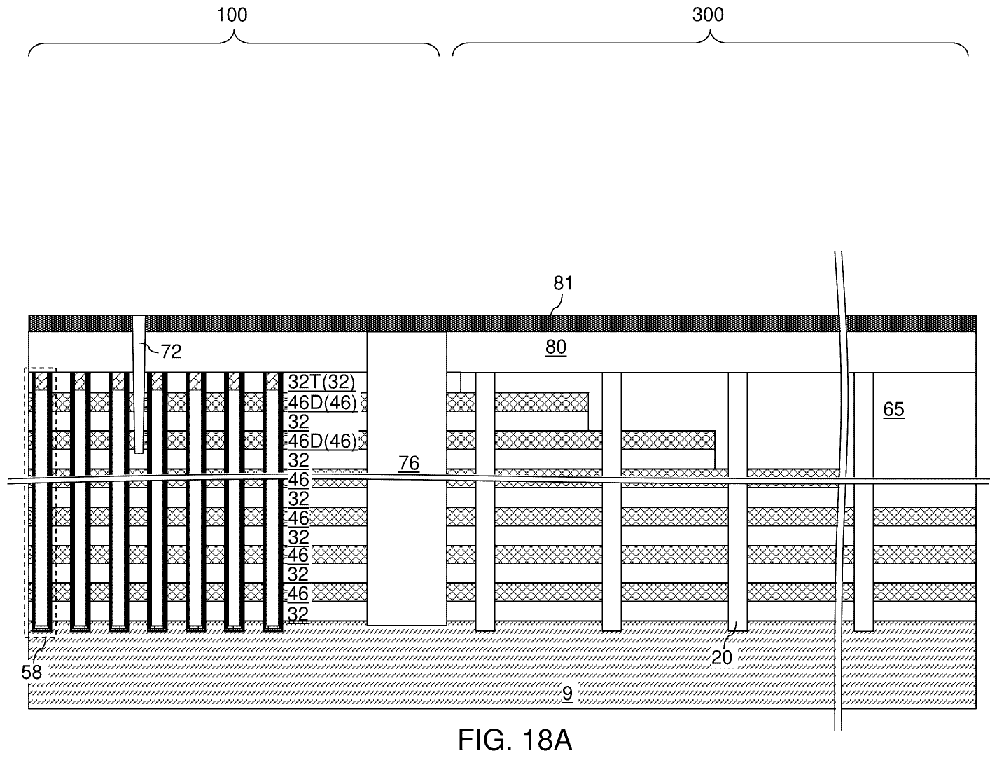

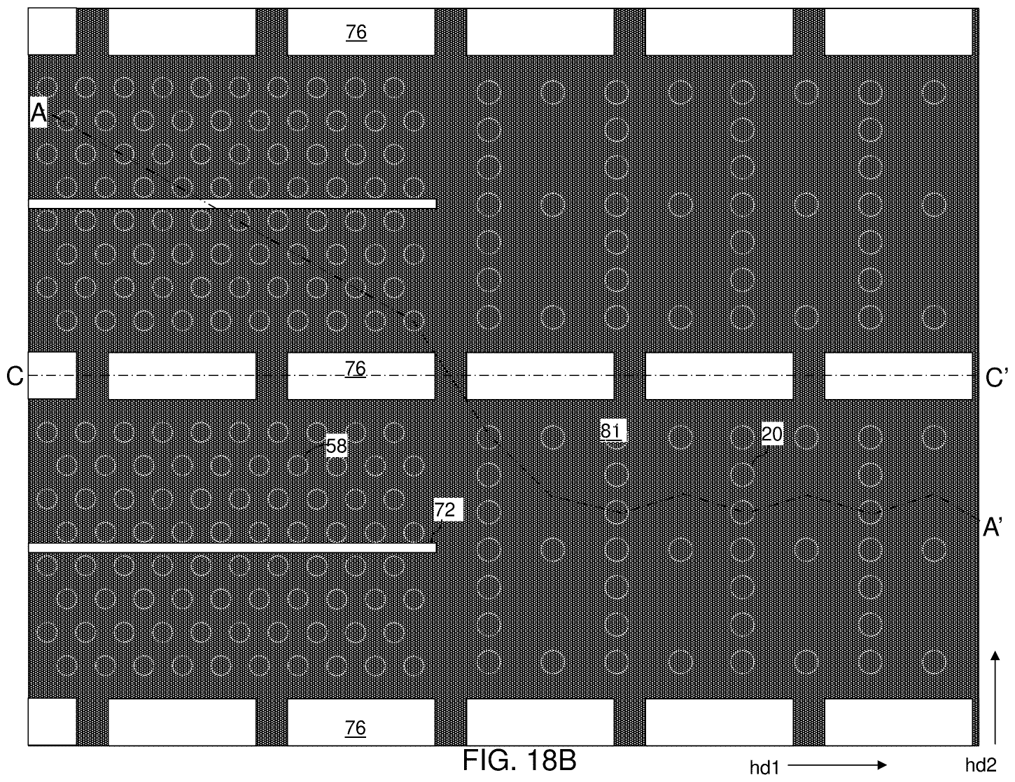

Referring to FIGS. 18A and 18B, a dielectric fill material, such as silicon oxide, can be deposited in the drain-select-level isolation trenches 73 to form drain-select-level isolation structures 72. Optionally, excess portions of the dielectric fill material may be removed from above the horizontal plane including the top surface of the perforated dielectric bridge layer 81.

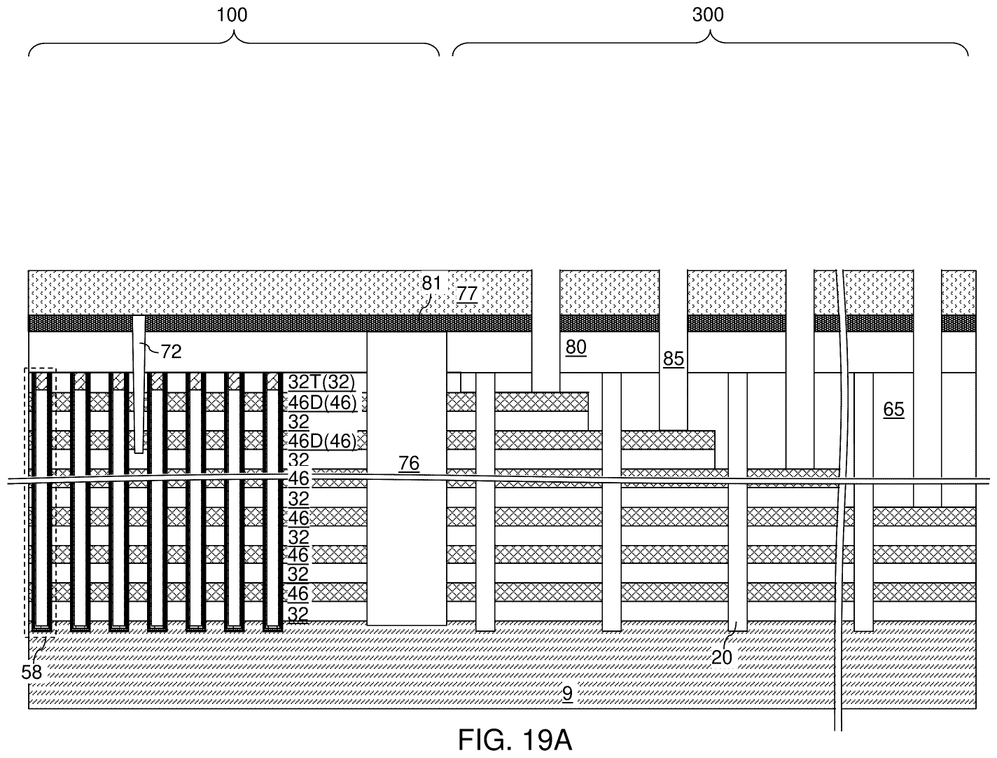

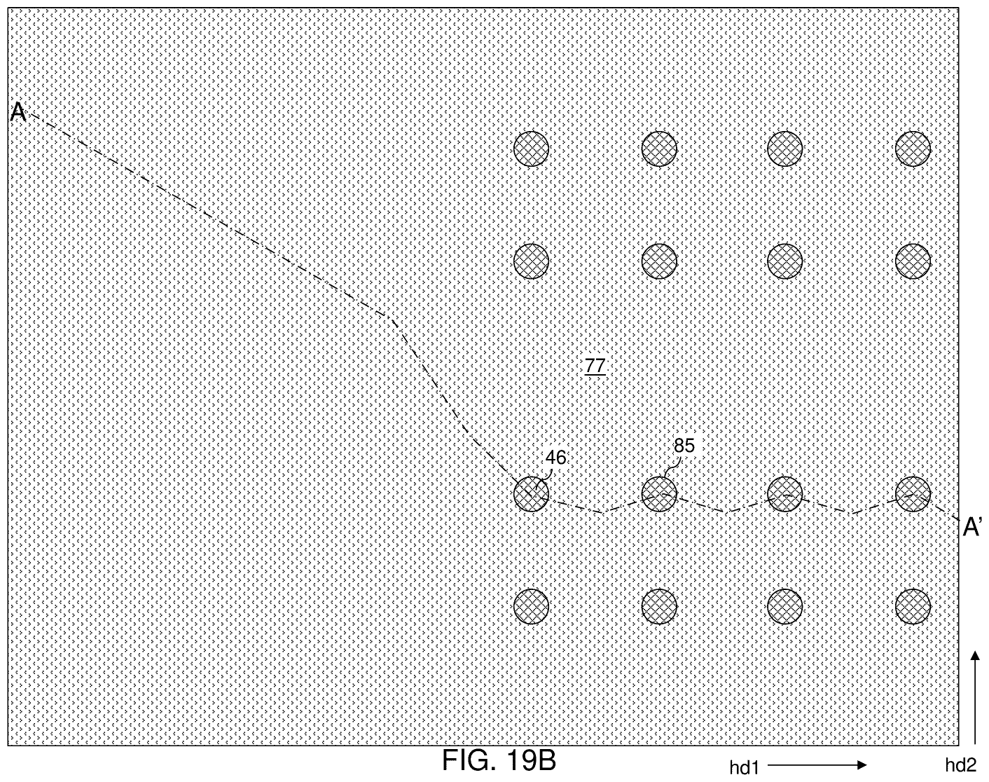

Referring to FIGS. 19A and 19B, a photoresist material layer can be applied over the perforated dielectric bridge layer 81, and can be lithographically patterned to form a second patterned photoresist layer 77 containing openings in areas in the contact region 300 that overlies a respective horizontally-extending surface segment of the electrically conductive layers 46. An anisotropic etch process can be performed to transfer the pattern of the openings in the second patterned photoresist layer 77 through the perforated dielectric bridge layer 81, the contact-level dielectric layers 80, and the retro-stepped dielectric material portion 65. Layer contact via cavities 85 can be formed through the perforated dielectric bridge layer 81, the contact-level dielectric layers 80, the retro-stepped dielectric material portion 65, and each outer blocking dielectric layer 44 (if present) in contact with a stepped bottom surface of the retro-stepped dielectric material portion 65 over a top surface of a respective one of the electrically conductive layers 46. Each electrically conductive layer 46 may have a top surface segment that is exposed to a respective overlying layer contact via cavity 85. The width of the bottoms of the layer contact via cavities 85 can be between 100 nm and 200 nm, such as between 125 nm and 175 nm, although lesser and greater widths may also be employed. The second patterned photoresist layer 77 can be subsequently removed, for example, by ashing.

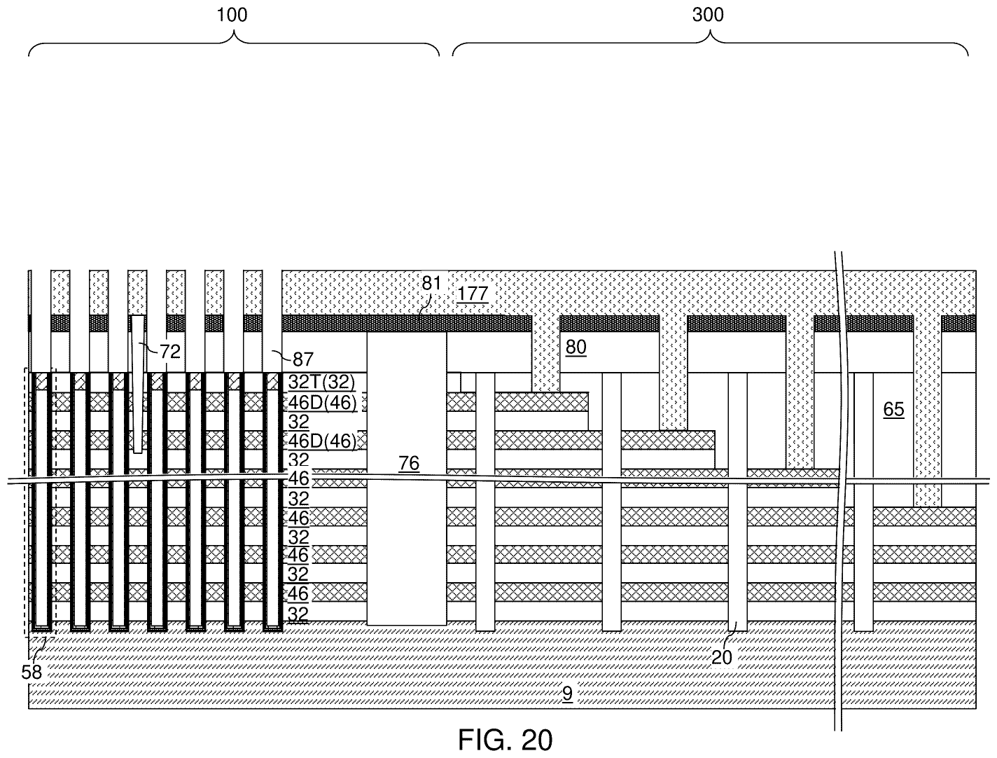

Referring to FIG. 20, a photoresist material layer can be applied over the perforated dielectric bridge layer 81, and can be lithographically patterned to form a third patterned photoresist layer 177 containing openings having the same pattern as the pattern of the memory opening fill structures 58. An anisotropic etch process can be performed to transfer the pattern of the openings in the third patterned photoresist layer 177 through the perforated dielectric bridge layer 81 and the contact-level dielectric layers 80. Drain contact via cavities 87 are formed through the perforated dielectric bridge layer 81 and the contact-level dielectric layers 80. A top surface of a drain region 63 can be physically exposed underneath each drain contact via cavity 87. The third patterned photoresist layer 177 can be subsequently removed, for example, by ashing. Alternatively, the drain contact via cavities 87 and the layer contact via cavities 85 may be formed during the same patterning and etching step using the second patterned photoresist layer 77 shown in FIGS. 19A and 19B. In this alternative embodiment, the third patterned photoresist layer 177 and the separate etching step shown in FIG. 20 may be omitted.

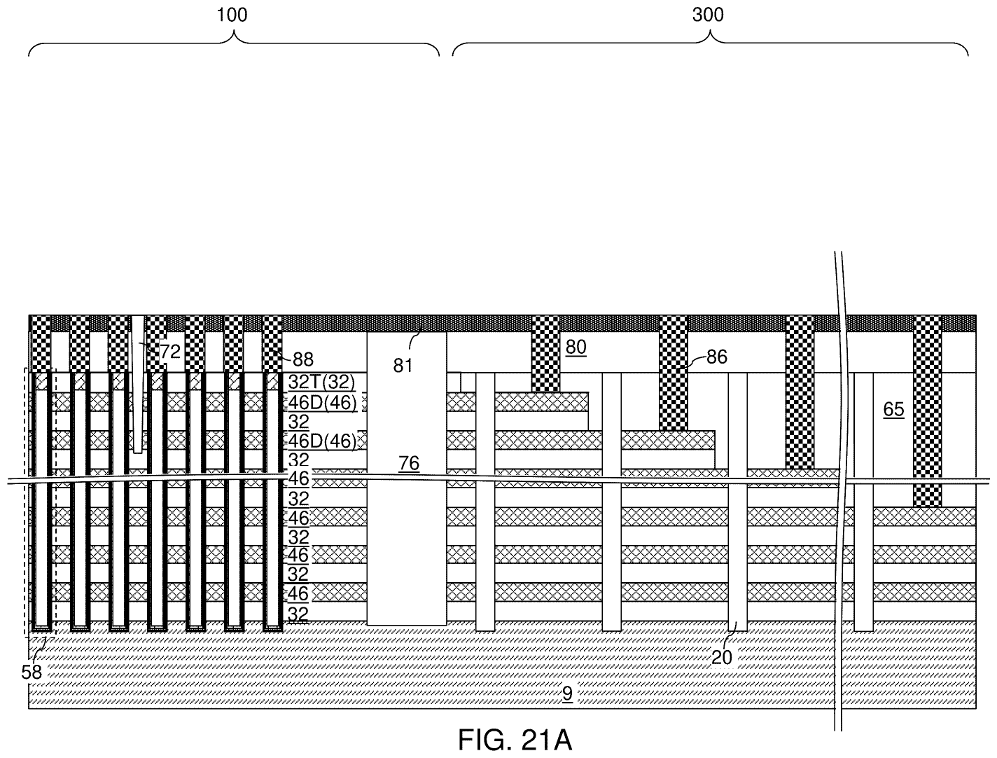

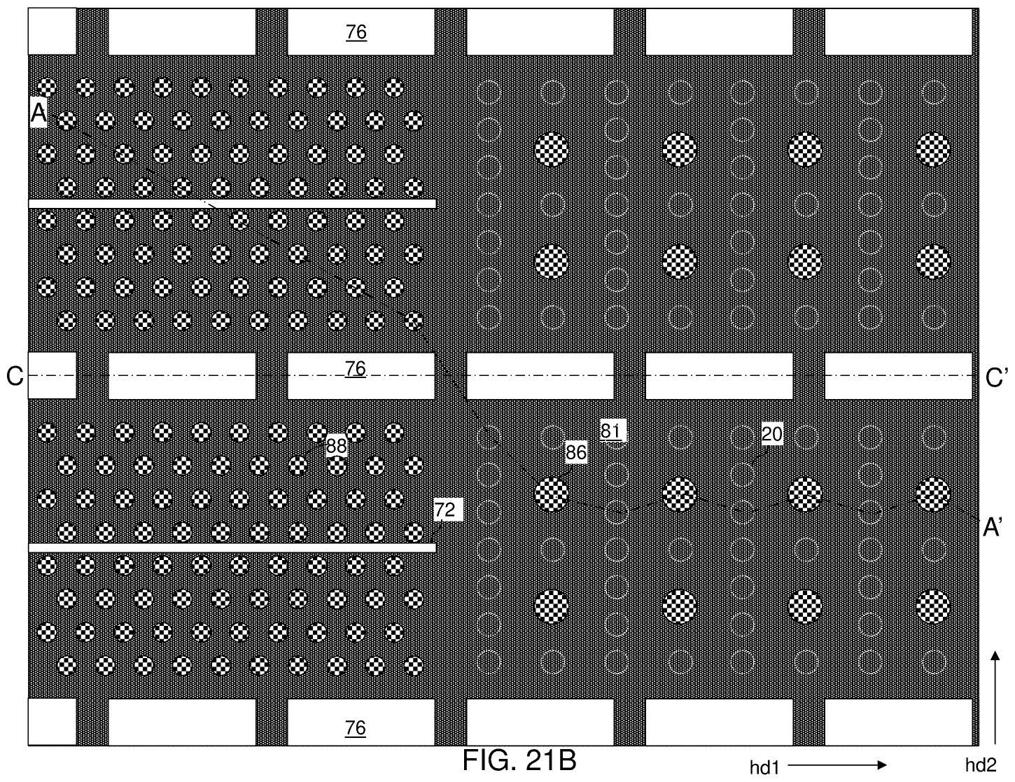

Referring to FIGS. 21A and 21B, at least one conductive material can be deposited in the layer contact via cavities 85, in the drain contact via cavities 87, and above the perforated dielectric bridge layer 81. The at least one conductive material may comprise a metallic barrier material (such as TiN, TaN, WN, and/or MoN) and a metal fill material (such as W, Cu, Mo, Ru, Co, Ti, Ta, etc.). Excess portions of the at least one conductive material can be removed from above the horizontal plane including the top surface of the perforated dielectric bridge layer 81 (if still present at this step) by performing a planarization process. The planarization process may comprise a chemical mechanical polishing process and/or a recess etch process. The perforated dielectric bridge layer 81 functions as a polish stop or an etch stop layer during the planarization process. Each remaining portion of the at least one conductive material that fills a respective layer contact via cavity 85 constitutes a layer contact via structure 86. In one embodiment, each layer contact via structure 86 may comprise a metallic barrier liner comprising a metallic barrier material and a metallic fill material portion comprising a metallic fill material. Drain contact via structures 88 are formed in the drain contact via cavities 87 concurrently with formation of the layer contact via structures 86 in the layer contact via cavities 85.

Generally, memory stack structures 55 are formed through the alternating stacks (32, 46). Each of the memory stack structures 55 comprises a vertical semiconductor channel 60 that vertically extends through a respective one of the alternating stacks (32, 46). Each of the vertical semiconductor channels 60 comprises a top end in contact with a respective drain region 63. The drain contact via structures 88 vertically extend through the perforated dielectric bridge layer 81 and a respective one of the contact-level dielectric layers 80 and contacts a respective one of the drain regions 63.

A staircase region is provided, in which the electrically conductive layers 46 within the alternating stacks (32, 46) have different lateral extents such that lateral extents of the electrically conductive layers 46 decrease with a vertical distance from a horizontal plane including bottommost surfaces of the alternating stacks (32, 46). The layer contact via structures 86 are located in the staircase region, and contact a respective one of the electrically conductive layers 46. Top surfaces of the layer contact via structures 86 and top surfaces of the drain contact via structures 88 are formed within a horizontal plane including a top surface of the perforated dielectric bridge layer 81.

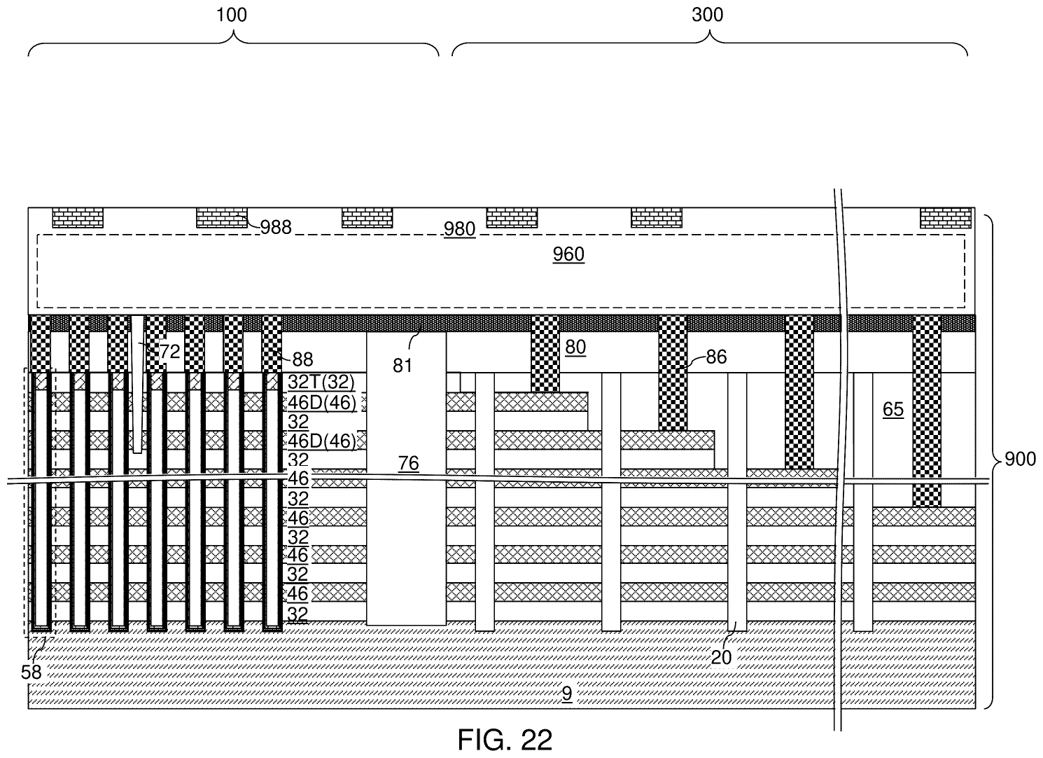

Referring to FIG. 22, additional dielectric material layers and additional metal interconnect structures can be formed over the perforated dielectric bridge layer 81. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The additional dielectric material layers that are formed above the perforated dielectric bridge layer 81 are herein referred to as memory-side dielectric material layers 960. The additional metal interconnect structures are collectively referred to as memory-side metal interconnect structures 980. The memory-side dielectric material layers 960 comprise a bit-line-level dielectric material layer embedding bit lines, which are a subset of the memory-side metal interconnect structures 980.

Metal bonding pads, which are herein referred to as memory-side bonding pads 988, may be formed at the topmost level of the memory-side dielectric material layers 960. The memory-side bonding pads 988 may be electrically connected to the memory-side metal interconnect structures 980 and various nodes of the three-dimensional memory array including the electrically conductive layers 46 and the memory opening fill structures 58. A memory die 900 can thus be provided.

The memory-side dielectric material layers 960 are formed over the alternating stacks (32, 46). The memory-side metal interconnect structures 980 are embedded in the memory-side dielectric material layers 960. The memory-side bonding pads 988 can be embedded within the memory-side dielectric material layers 960, and specifically, within the topmost layer among the memory-side dielectric material layers 960. The memory-side bonding pads 988 can be electrically connected to the memory-side metal interconnect structures 980.

In one embodiment, the memory die 900 may comprise: a three-dimensional memory array comprising an alternating stack (32, 46) of insulating layers 32 and electrically conductive layers 46, a two-dimensional array of memory openings 49 vertically extending through the alternating stack (32, 46), and a two-dimensional array of memory opening fill structures 58 located in the two-dimensional array of memory openings 49 and comprising a respective vertical stack of memory elements and a respective vertical semiconductor channel 60; and a two-dimensional array of contact via structures (such as the drain contact via structures 88) overlying the three-dimensional memory array and electrically connected to a respective one of the vertical semiconductor channels 60.

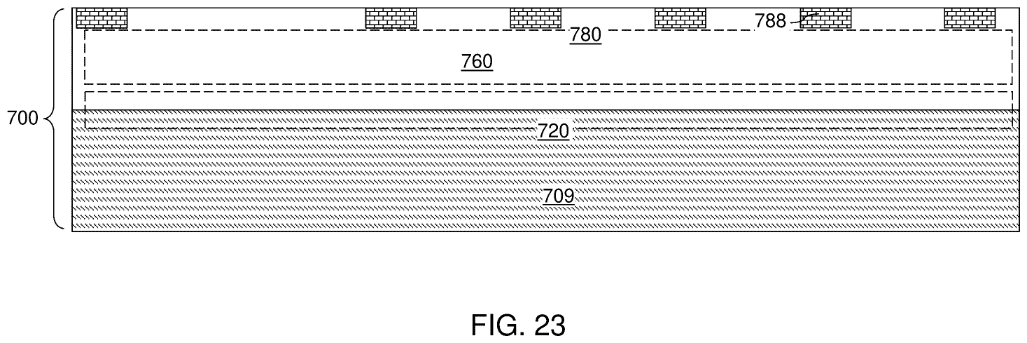

Referring to FIG. 23, a logic die 700 can be provided. The logic die 700 includes a logic-side substrate 709, a peripheral circuit 720 located on the logic-side substrate 709 and comprising logic-side semiconductor devices (such as field effect transistors), logic-side metal interconnect structures 780 embedded within logic-side dielectric material layers 760, and logic-side bonding pads 788. The peripheral circuit 720 can be configured to control operation of the memory array within the memory die 900. Specifically, the peripheral circuit 720 can be configured to drive various electrical components within the memory array including, but not limited to, the electrically conductive layers 46, the drain regions 63, and a source contact structure to be subsequently formed. The peripheral circuit 720 can be configured to control operation of the vertical stack of memory elements in the memory array in the memory die 900.

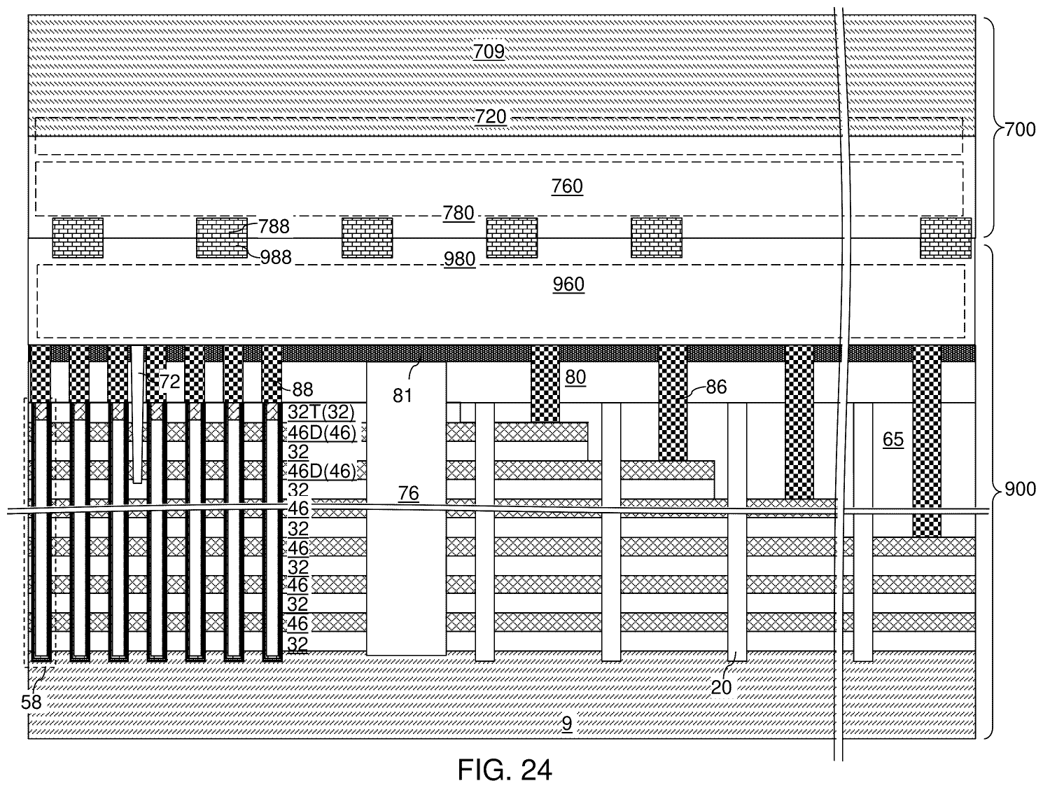

Referring to FIG. 24, the logic die 700 can be attached to the memory die 900, for example, by bonding the logic-side bonding pads 788 to the memory-side bonding pads 988 at a bonding interface. The bonding between the memory die 900 and the logic die 700 may be performed employing a wafer-to-wafer bonding process in which a two-dimensional array of memory dies 900 is bonded to a two-dimensional array of logic dies 700, by a die-to-wafer bonding process, or by a die-to-die bonding process. The logic-side bonding pads 788 within each logic die 700 can be bonded to the memory-side bonding pads 988 within a respective memory die 900.

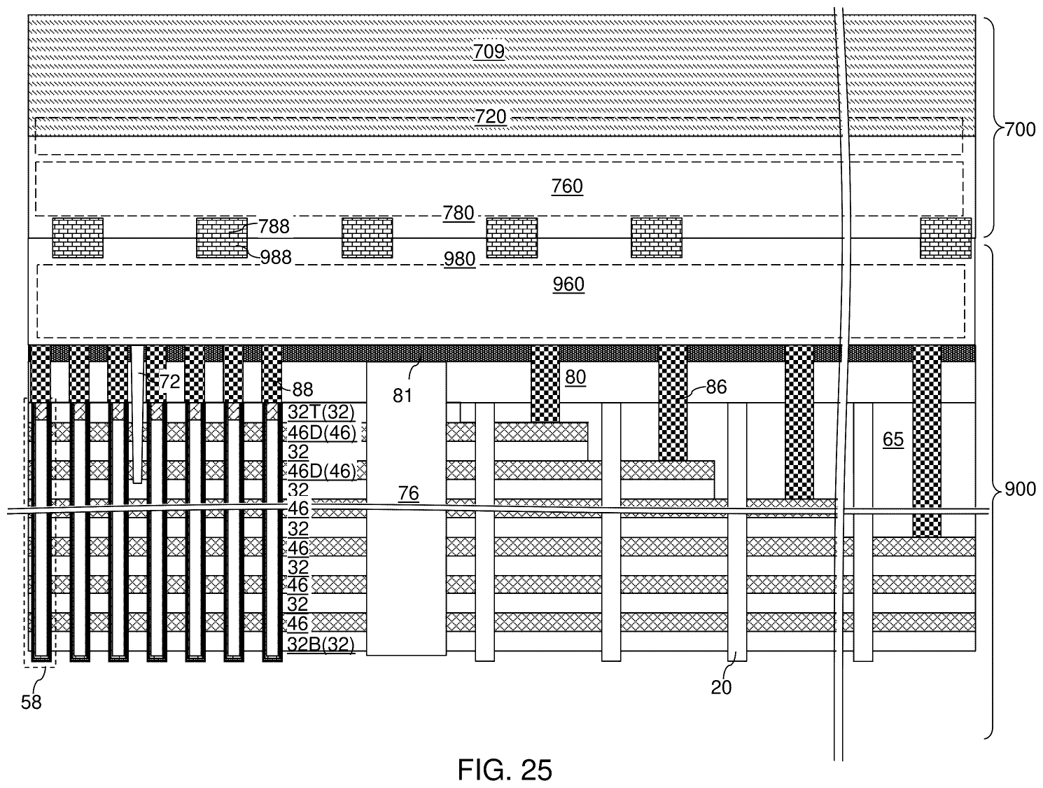

Referring to FIG. 25, the carrier substrate 9 can be removed, for example, by grinding, polishing, cleaving, an isotropic etch process, an anisotropic etch process, and/or a combination thereof. If a chemical mechanical polishing process or an etch process is employed as a terminal step for removing the carrier substrate 9, the bottommost insulating layers 32B may be employed as a polish stop or etch stop, respectively.

In one embodiment, at least a terminal step of at least one removal process that is employed to remove the carrier substrate 9 may comprise a selective wet etch process that etches the material of the carrier substrate 9 (such as a semiconductor material of the carrier substrate 9) selectively to dielectric materials of the memory films 50. In an illustrative example, if the carrier substrate 9 comprises a semiconductor material, the terminal step of the at least one removal process may comprise a wet etch process using hot trimethyl-2 hydroxyethyl ammonium hydroxide (“hot TMY”) or tetramethyl ammonium hydroxide (TMAH). The entirety of the carrier substrate 9 can be removed by the selective wet etch process. Backside end surfaces of the support pillar structures 20 can be physically exposed upon removal of the carrier substrate 9.

A sequence of wet etch steps can be performed to sequentially remove portions of the memory film 50 that are exposed on the backside of the alternating stack (32, 46). For example, the inner blocking dielectric layer 52, the memory material layer 54, and the optional dielectric liner 56 (which may be, for example, a tunneling dielectric layer) of each memory film 50 can be removed from a region that is more distal from the bonding interface between the memory die 900 and the logic die 700 than a physically exposed planar surface of the bottommost insulating layers 32B is from the bonding interface. The blocking dielectric layer 52, the memory material layer 54, and the optional dielectric liner 56 (which may be, for example, a tunneling dielectric layer) of each memory film 50 can be removed from below the horizontal plane including the bottom surface of the bottommost insulating layers 32B.

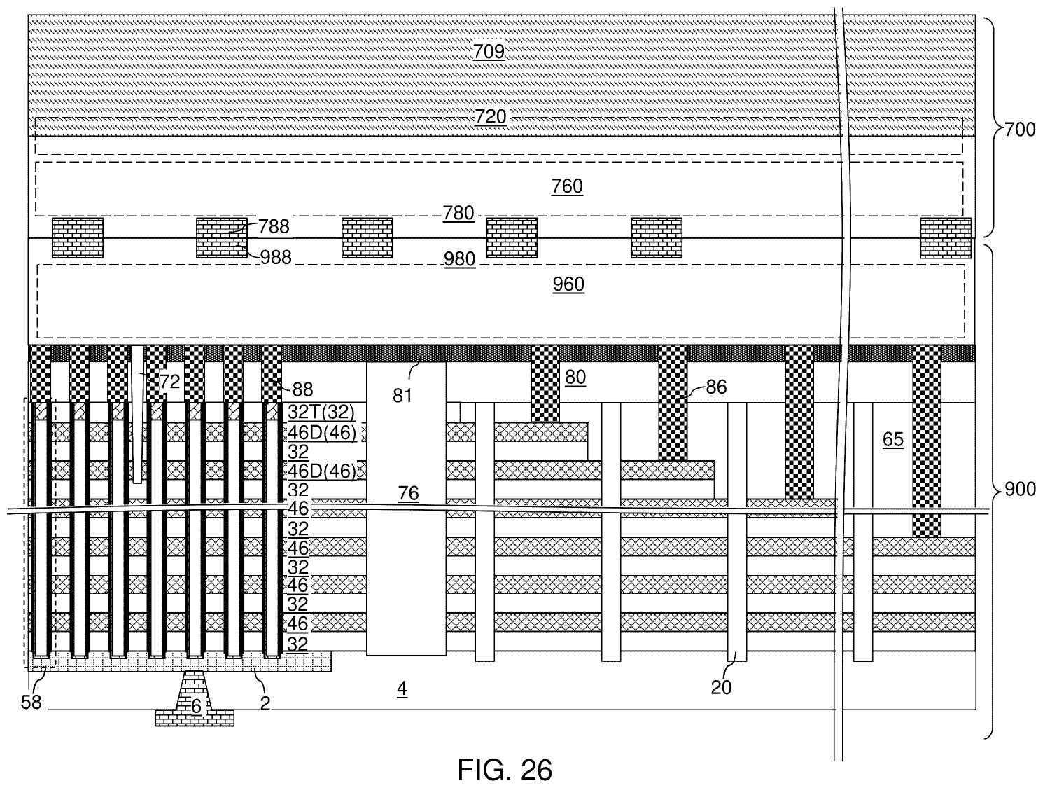

Referring to FIG. 26, source structures 2 (such as at least one heavily doped semiconductor and/or metallic source layer), a backside dielectric layer 5, and backside contact via structures 6 can be subsequently formed.

Referring to all drawings and according to various embodiments of the present disclosure, a memory device comprises: alternating stacks (32, 46) of insulating layers 32 and electrically conductive layers 46, wherein the alternating stacks (32, 46) are laterally spaced apart from each other by lateral isolation trenches 79 that laterally extend along a first horizontal direction hd1; arrays of memory stack structures 55, wherein each array of memory stack structures 55 vertically extends through a respective one of the alternating stacks (32, 46), and each of the memory stack structures 55 comprises a respective vertical semiconductor channel and vertical stack of memory elements; and a perforated dielectric bridge layer 81 laterally extending over each of the alternating stacks (32, 46) and each of the lateral isolation trenches 79 and comprising rows of elongated openings 89 therethrough, wherein each row of elongated openings 89 overlies a respective one of the lateral isolation trenches 79 and extends along the first horizontal direction hd1.

In one embodiment, the memory device further comprises lateral isolation wall structures 76 filling the lateral isolation trenches 79 and the elongated openings 89 in the perforated dielectric bridge layer 81. In one embodiment, each of the lateral isolation wall structures 76 comprises a primary dielectric wall portion 76P filling a respective one of the lateral isolation trenches 79 and a row of castellated protrusions 76C located above the primary dielectric wall portion 76P and filling a respective row of elongated openings 89 in the perforated dielectric bridge layer 81. In one embodiment, top surfaces of the lateral isolation wall structures 76 are located within a horizontal plane including a top surface of the perforated dielectric bridge layer 81. In one embodiment, the lateral isolation wall structures 76 contact all sidewall surfaces of the elongated openings 89 in the perforated dielectric bridge layer 81.

In one embodiment, the perforated dielectric bridge layer 81 is a single continuous material layer; and neighboring pairs of elongated openings 89 within each row of elongated openings 89 are laterally spaced by bridge portions of the perforated dielectric bridge layer 81 that extend over a respective one of the lateral isolation trenches 79.

In one embodiment, each row of elongated openings 89 that overlies the respective one of the lateral isolation trenches 79 comprises lengthwise opening sidewalls laterally extending along the first horizontal direction hd1 and laterally offset from a most proximal lengthwise sidewall of the respective one of the lateral isolation trenches 79 by a lateral offset distance along a second horizontal direction hd2 that is perpendicular to the first horizontal direction hd1.

In one embodiment, the memory device comprises contact-level dielectric layers 80 overlying a respective one of the alternating stacks (32, 46) and laterally spaced apart from each other by the lateral isolation trenches 79, wherein top edges of the lateral isolation trenches 79 are located within a horizontal plane including top surfaces of the contact-level dielectric layers 80. In one embodiment, the contact-level dielectric layers 80 comprise a first dielectric material; and the perforated dielectric bridge layer 81 comprises a second dielectric material that is different from the first dielectric material. In one embodiment, the first dielectric material comprises silicon oxide; and the second dielectric material comprises silicon carbonitride, silicon oxycarbide, or a dielectric metal oxide.

In one embodiment, each of the vertical semiconductor channels 60 comprises a top end in contact with a respective drain region 63; and the memory device also comprises drain contact via structures 88 vertically extending through the perforated dielectric bridge layer 81 and a respective one of the contact-level dielectric layers 80 and contacting a respective one of the drain regions 63.

In one embodiment, the memory device comprises: a staircase region in which the electrically conductive layers 46 within the alternating stacks (32, 46) have different lateral extents; and layer contact via structures 86 located in the staircase region and contacting a respective one of the electrically conductive layers 46, wherein top surfaces of the layer contact via structures 86 are located within a horizontal plane including a top surface of the perforated dielectric bridge layer 81.

In one embodiment, each of the elongated openings 89 in the perforated dielectric bridge layer 81 comprises a respective pair of lengthwise opening sidewalls that are parallel to the first horizontal direction hd1 and a respective pair of widthwise opening sidewalls that are parallel to a second horizontal direction hd2 that is perpendicular to the first horizontal direction hd1; each of the elongated openings 89 has a respective first lateral extent along the first horizontal direction hd1 and a respective second lateral extent along the second horizontal direction hd2; and a ratio of the respective first lateral extent to the respective second lateral extent is in a range from 2 to 30. In one embodiment, the respective second lateral extent is in a range from 60% to 200% of a width of each of the lateral isolation trenches 79 along the second horizontal direction hd2.

The bridge portions 81B of the perforated dielectric bridge layer 81 act as stiffener structures during replacement of the sacrificial material layers 42 with electrically conductive layers 46, thus reducing or preventing lateral tilting of the insulating layers 32 into the lateral isolation trenches 79. Since the perforated dielectric bridge layer 81 is located above the alternating stacks (32, 46) rather than inside the dielectric isolation trenches 79 at levels of the alternating stacks (32, 46), the process cost may be reduced and improved thickness control of the bridge portions 81B may be achieved. Furthermore, by forming the perforated dielectric bridge layer 81 from a material different than that of the sacrificial material layers 42, the perforated dielectric bridge layer 81 is not removed during the etching of the sacrificial material layers. The perforated dielectric bridge layer 81 also functions as polish stop or etch stop layer during one or more planarization steps. Thus, the perforated dielectric bridge layer 81 reduces thickness variation of various layers (such as interlayer dielectric layer(s)) of the memory device.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A memory device, comprising:
alternating stacks of insulating layers and electrically conductive layers, wherein the alternating stacks are laterally spaced apart from each other by lateral isolation trenches that laterally extend along a first horizontal direction;
arrays of memory stack structures, wherein each array of memory stack structures vertically extends through a respective one of the alternating stacks, and each of the memory stack structures comprises a respective vertical semiconductor channel and a vertical stack of memory elements; and
a perforated dielectric bridge layer laterally extending over each of the alternating stacks and each of the lateral isolation trenches and comprising rows of elongated openings therethrough, wherein each row of elongated openings overlies a respective one of the lateral isolation trenches and extends along the first horizontal direction.

2. The memory device of claim 1, further comprising lateral isolation wall structures filling the lateral isolation trenches and the elongated openings in the perforated dielectric bridge layer.

3. The memory device of claim 2, wherein each of the lateral isolation wall structures comprises a primary dielectric wall portion filling a respective one of the lateral isolation trenches and a row of castellated protrusions located above the primary dielectric wall portion and filling a respective row of elongated openings in the perforated dielectric bridge layer.

4. The memory device of claim 2, wherein top surfaces of the lateral isolation wall structures are located within a horizontal plane including a top surface of the perforated dielectric bridge layer.

5. The memory device of claim 2, wherein the lateral isolation wall structures contact all sidewall surfaces of the elongated openings in the perforated dielectric bridge layer.

6. The memory device of claim 1, wherein:
the perforated dielectric bridge layer is a single continuous material layer; and
neighboring pairs of elongated openings within each row of elongated openings are laterally spaced by bridge portions of the perforated dielectric bridge layer that extend over a respective one of the lateral isolation trenches.

7. The memory device of claim 1, wherein said each row of elongated openings that overlies the respective one of the lateral isolation trenches comprises lengthwise opening sidewalls laterally extending along the first horizontal direction and laterally offset from a most proximal lengthwise sidewall of the respective one of the lateral isolation trenches by a lateral offset distance along a second horizontal direction that is perpendicular to the first horizontal direction.

8. The memory device of claim 1, further comprising contact-level dielectric layers overlying a respective one of the alternating stacks and laterally spaced apart from each other by the lateral isolation trenches, wherein top edges of the lateral isolation trenches are located within a horizontal plane including top surfaces of the contact-level dielectric layers.

9. The memory device of claim 8, wherein:
the contact-level dielectric layers comprise a first dielectric material; and
the perforated dielectric bridge layer comprises a second dielectric material that is different from the first dielectric material.

10. The memory device of claim 9, wherein:
the first dielectric material comprises silicon oxide; and
the second dielectric material comprises silicon carbonitride, silicon oxycarbide, or a dielectric metal oxide.

11. The memory device of claim 8, wherein:
each of the vertical semiconductor channels comprises a top end in contact with a respective drain region; and
the memory device further comprises drain contact via structures vertically extending through the perforated dielectric bridge layer and a respective one of the contact-level dielectric layers and contacting a respective one of the drain regions.

12. The memory device of claim 1, further comprising:
a staircase region in which the electrically conductive layers within the alternating stacks have different lateral extents; and
layer contact via structures located in the staircase region and contacting a respective one of the electrically conductive layers, wherein top surfaces of the layer contact via structures are located within a horizontal plane including a top surface of the perforated dielectric bridge layer.

13. The memory device of claim 1, wherein:
each of the elongated openings in the perforated dielectric bridge layer comprises a respective pair of lengthwise opening sidewalls that are parallel to the first horizontal direction and a respective pair of widthwise opening sidewalls that are parallel to a second horizontal direction that is perpendicular to the first horizontal direction;
each of the elongated openings has a respective first lateral extent along the first horizontal direction and a respective second lateral extent along the second horizontal direction;
a ratio of the respective first lateral extent to the respective second lateral extent is in a range from 2 to 30; and
the respective second lateral extent is in a range from 60% to 200% of a width of each of the lateral isolation trenches along the second horizontal direction.

14. The memory device of claim 1, wherein the perforated dielectric bridge layer comprises silicon carbonitride.

15. A method of forming a device structure, comprising:
forming a plurality of alternating stacks of insulating layers and sacrificial material layers that are laterally spaced apart from each other by lateral isolation trenches that laterally extend along a first horizontal direction;
forming sacrificial lateral isolation wall structures in the lateral isolation trenches;
forming a perforated dielectric bridge layer over the plurality of alternating stacks and sacrificial lateral isolation wall structures, wherein the perforated dielectric bridge layer comprises rows of elongated openings therethrough, and wherein each row of elongated openings overlies a respective one of the sacrificial lateral isolation wall structures and is arranged along the first horizontal direction;
removing the sacrificial lateral isolation wall structures through the rows of elongated openings without removing the plurality of alternating stacks or the perforated dielectric bridge layer; and
replacing the sacrificial material layers with at least electrically conductive layers.

16. The method of claim 15, further comprising:
forming a vertically alternating sequence of continuous insulating layers and continuous sacrificial material layers over a substrate;
forming memory openings through the vertically alternating sequence;
forming memory opening fill structures in the memory openings, wherein each of the memory opening fill structures comprises a respective vertical semiconductor channel and a vertical stack of memory elements; and
forming the lateral isolation trenches through the vertically alternating sequence, wherein patterned portions of the vertically alternating sequence comprise the plurality of alternating stacks.

17. The method of claim 16, further comprising:
forming drain regions on the vertical semiconductor channels; and
forming drain contact via structures through the perforated dielectric bridge layer on the drain regions.

18. The method of claim 15, further comprising forming lateral recesses by performing an isotropic etch process that etches the sacrificial material layers without etching the insulating layers or the perforated dielectric bridge layer, wherein the electrically conductive layers are formed by performing a conformal deposition process during which the rows of elongated openings and the lateral isolation trenches are employed as conduits for providing a reactant that forms the electrically conductive layers upon decomposition.

19. The method of claim 18, further comprising forming lateral isolation wall structures by filling volumes of the lateral isolation trenches and the elongated openings in the perforated dielectric bridge layer.

20. The method of claim 18, wherein:
the perforated dielectric bridge layer comprises silicon carbonitride; and
each of the lateral isolation wall structures comprises a primary dielectric wall portion that fills a respective one of the lateral isolation wall structures and further comprises a row of castellated protrusions adjoined to the primary dielectric wall portion and fills a respective row of elongated openings in the perforated dielectric bridge layer.
